(19) United States
(12) Patent Application Publication
(10) Pub. No.: US 2026/0282842 A1
(43) Pub. Date: Sep. 17, 2026

(54) CRYSTAL EVALUATION METHOD

(71) Applicant: Kioxia Corporation, Tokyo (JP)

(72) Inventors: Kyosuke YOSHIOKA, Yokkaichi (JP); Yurika KANNO, Yokkaichi (JP)

(73) Assignee: Kioxia Corporation, Tokyo (JP)

(21) Appl. No.: 19/234,488

(22) Filed: Jun. 11, 2025

(30) Foreign Application Priority Data
Mar. 17, 2025 (JP) 2025-042301

(51) Int. Cl. H01L 21/66; G01N 21/88; G01N 23/2252; H01L 21/306

(52) U.S. Cl. CPC H10P 74/203; G01N 21/8851; G01N 23/2252; H10P 50/642; G01N 2223/079; G01N 2223/102; G01N 2223/405; G01N 2223/41

(57) ABSTRACT

In one embodiment, a crystal evaluation method includes forming, above a first substrate, a semiconductor layer that includes an amorphous layer containing metal atoms, the semiconductor layer including a first portion and a second portion. The method further includes crystallizing the first portion from the amorphous layer into a crystalline layer. The method further includes treating the semiconductor layer with a chemical liquid that dissolves at least a part of the first portion or the second portion. The method further includes determining a crystallization state of the semiconductor layer after the treatment.

### CROSS REFERENCE TO RELATED APPLICATION

This application is based upon and claims the benefit of priority from the prior Japanese Patent Application No. 2025-042301, filed on Mar. 17, 2025, the entire contents of which are incorporated herein by reference.

### FIELD

Embodiments described herein relate to a crystal evaluation method.

### BACKGROUND

A method of cleaving a wafer is known for evaluating the crystallinity of a channel semiconductor layer in a semiconductor device.

### BRIEF DESCRIPTION OF THE DRAWINGS

FIG. 1 is a cross-sectional view showing a structure of a semiconductor device of a first embodiment;

FIG. 2 is a plan view showing the structure of the semiconductor device of the first embodiment;

FIGS. 3 to 12 are cross-sectional views showing a method of manufacturing the semiconductor device of the first embodiment;

FIGS. 13 to 15 are cross-sectional views showing a method of manufacturing a semiconductor device of a modification of the first embodiment;

FIGS. 16 and 17 are cross-sectional views showing a first example of a crystal evaluation method of the first embodiment;

FIG. 18 is a plan view showing the first example of the crystal evaluation method of the first embodiment;

FIGS. 19 and 20 are cross-sectional views showing the first example of the crystal evaluation method of the first embodiment;

FIGS. 21 to 25 are cross-sectional views showing a second example of the crystal evaluation method of the first embodiment;

FIGS. 26 and 27 are cross-sectional views showing the second example of the crystal evaluation method of the first embodiment;

FIGS. 28 and 29 are plan views showing the second example of the crystal evaluation method of the first embodiment;

FIGS. 30 to 32 are cross-sectional views showing a modification of the second example of the crystal evaluation method of the first embodiment;

FIGS. 33 and 34 are plan views showing the modification of the second example of the crystal evaluation method of the first embodiment;

FIGS. 35 to 38 are cross-sectional views showing a third example of the crystal evaluation method of the first embodiment;

FIG. 39 is a cross-sectional view showing a structure of a semiconductor device of a second embodiment;

FIG. 40 is an enlarged cross-sectional view showing the structure of the semiconductor device of the second embodiment; and

FIGS. 41 and 42 are cross-sectional views showing a method of manufacturing the semiconductor device of the second embodiment.

### DETAILED DESCRIPTION

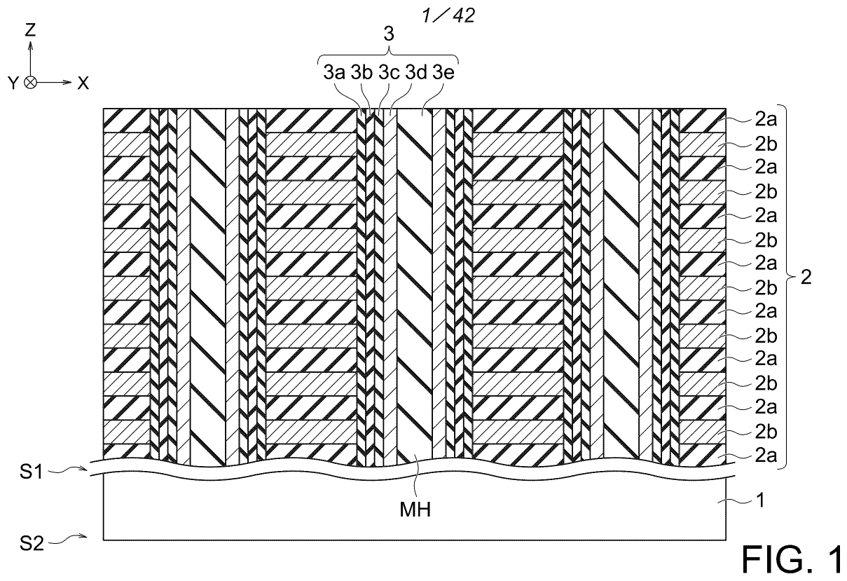

Embodiments will now be explained with reference to the accompanying drawings. In FIG. 1 to 42, the same components are denoted by the same reference numerals and characters, and duplicated description is omitted.

In one embodiment, a crystal evaluation method includes forming, above a first substrate, a semiconductor layer that includes an amorphous layer containing metal atoms, the semiconductor layer including a first portion and a second portion. The method further includes crystallizing the first portion from the amorphous layer into a crystalline layer. The method further includes treating the semiconductor layer with a chemical liquid that dissolves at least a part of the first portion or the second portion. The method further includes determining a crystallization state of the semiconductor layer after the treatment.

### First Embodiment

FIG. 1 is a cross-sectional view showing a structure of a semiconductor device of a first embodiment. The semiconductor device of this embodiment includes, for example, a three-dimensional semiconductor memory.

The semiconductor device of this embodiment includes a substrate 1, a stacked film 2, and a plurality of columnar portions 3. The stacked film 2 includes a plurality of insulators 2a and a plurality of electrode layers 2b. Each columnar portion 3 includes a block insulator 3a, a charge storage layer 3b, a tunnel insulator 3c, a channel semiconductor layer 3d, and a core insulator 3e. The substrate 1 is an example of a first substrate. The stacked film 2 is an example of a first film. The channel semiconductor layer 3d is an example of a semiconductor layer and a crystalline layer.

The substrate 1 is, for example, a semiconductor substrate such as a Si (silicon) substrate. FIG. 1 shows an X direction and a Y direction that are parallel to an upper face S1 and a lower face S2 of the substrate 1 and perpendicular to each other, and a Z direction that is perpendicular to the upper face S1 and the lower face S2 of the substrate 1. In this specification, the +Z direction is defined as the upward direction, and the −Z direction is defined as the downward direction. The −Z direction may or may not coincide with the direction of gravity.

The stacked film 2 is formed on the substrate 1. The stacked film 2 may be formed on the substrate 1 via another film. The stacked film 2 includes a plurality of insulators 2a and a plurality of electrode layers 2b provided alternately in the Z direction. Each insulator 2a is, for example, a SiO₂ film (silicon oxide film). Each electrode layer 2b is, for example, a metal layer including a W (tungsten) layer. In this embodiment, each electrode layer 2b functions as, for example, a word line, a source side selection line, or a drain side selection line.

Each columnar portion 3 is formed in the stacked film 2. Specifically, each columnar portion 3 extends in the Z direction and has a circular shape in a plan view. In this embodiment, each columnar portion 3 penetrates the stacked film 2 in the Z direction. Each columnar portion 3 includes a block insulator 3a, a charge storage layer 3b, a tunnel insulator 3c, a channel semiconductor layer 3d, and a core insulator 3e that are formed in sequence on the side face of the stacked film 2. FIG. 1 further shows a plurality of memory holes MH formed in the stacked film 2. Each columnar portion 3 is formed in a corresponding one of the memory holes MH.

In each columnar portion 3, the block insulator 3a is, for example, a SiO₂ film. The charge storage layer 3b is, for example, an insulator such as a SiN film (silicon nitride film). The charge storage layer 3b may be a semiconductor layer such as a polycrystalline silicon layer (polysilicon layer). The charge storage layer 3b of this embodiment can store signal charges of a three-dimensional semiconductor memory. The tunnel insulator 3c is, for example, a SiO₂ film. The channel semiconductor layer 3d is, for example, a polycrystalline semiconductor layer such as a polycrystalline silicon layer. The channel semiconductor layer 3d may be a single crystal semiconductor layer such as a single crystal silicon layer. The channel semiconductor layer 3d of this embodiment functions as channels of a plurality of cell transistors (memory cells) and a plurality of selection transistors in the three-dimensional semiconductor memory. The core insulator 3e is, for example, a SiO₂ film.

Note that the semiconductor device of this embodiment does not necessarily have to include the substrate 1. For example, when two or more substrates are bonded to manufacture the semiconductor device of this embodiment, the semiconductor device of this embodiment may have a substrate above the stacked film 2 instead of having a substrate 1 below the stacked film 2.

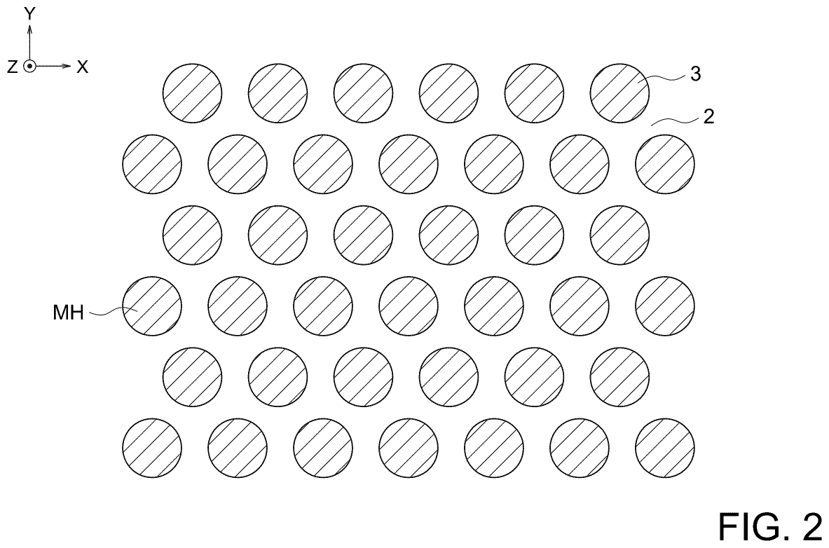

FIG. 2 is a plan view showing the structure of a semiconductor device of a first embodiment.

As shown in FIG. 2, the semiconductor device of this embodiment includes a plurality of columnar portions 3 placed in a two-dimensional array. FIG. 1 shows three of these columnar portions 3. Although these columnar portions 3 are placed in a triangular lattice in FIG. 2, they may be placed in other layouts.

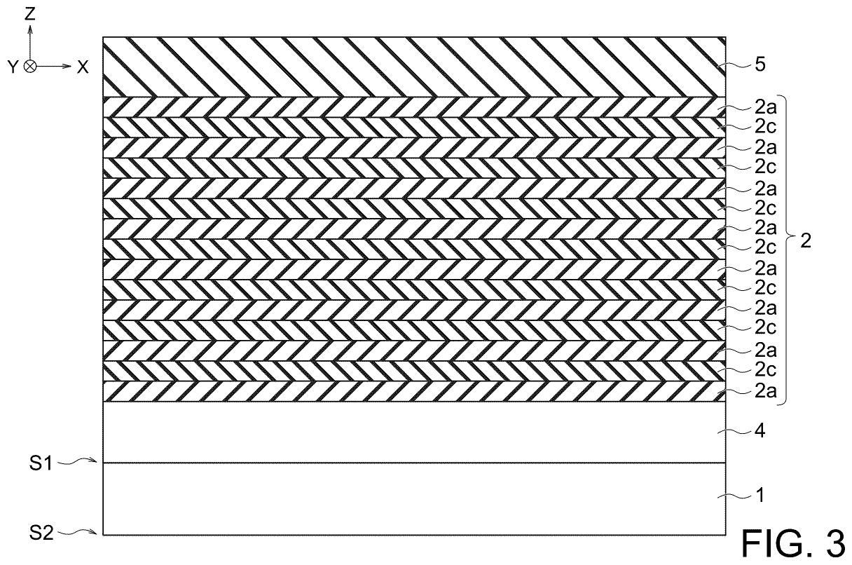

FIGS. 3 to 12 are cross-sectional views showing a method of manufacturing the semiconductor device of the first embodiment.

First, an underlayer 4 is formed on the substrate 1, the stacked film 2 is formed on the underlayer 4, and an insulator 5 is formed on the stacked film 2 (FIG. 3). The underlayer 4 includes, for example, an insulator such as an inter layer dielectric. The stacked film 2 is formed by alternately stacking a plurality of insulators 2a and a plurality of sacrificial layers 2c on the underlayer 4. In FIG. 3, the stacked film 2 includes a plurality of insulators 2a and a plurality of sacrificial layers 2c alternately provided in the Z direction. Each insulator 2a is an example of a first layer, and each sacrificial layer 2c is an example of a second layer. Each sacrificial layer 2c is, for example, a SiN film. The insulator 5 is, for example, a SiO₂ film. The underlayer 4, the stacked film 2, and the insulator 5 are examples of a first film.

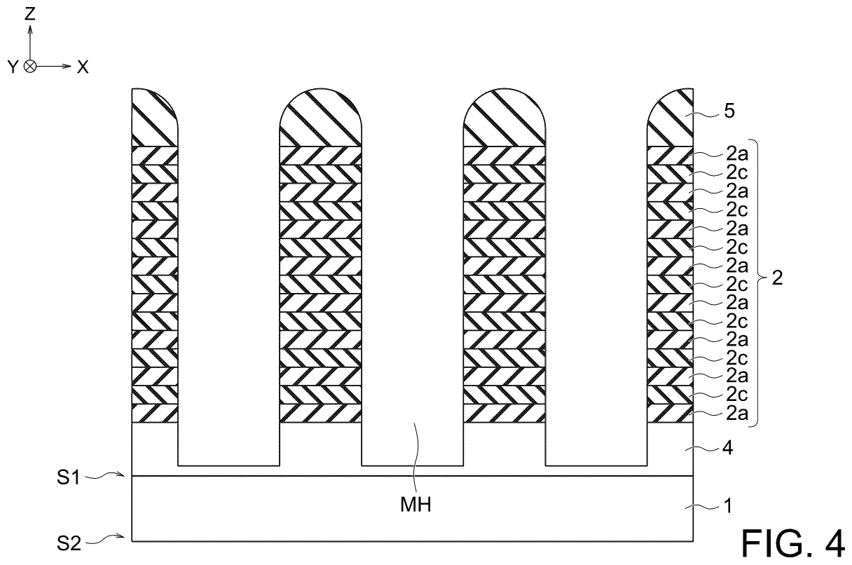

Next, a plurality of memory holes MH are formed in the insulator 5, the stacked film 2, and the underlayer 4 by lithography and reactive ion etching (RIE) (FIG. 4). Each memory hole MH in this embodiment is formed to penetrate the insulator 5 and the stacked film 2 and have its bottom face in the underlayer 4.

In FIG. 4, the cross-sectional shape of the upper face of the insulator 5 is convex. Such a cross-sectional shape may be formed by the RIE, or may be formed by a process after the RIE (for example, an ion implant process).

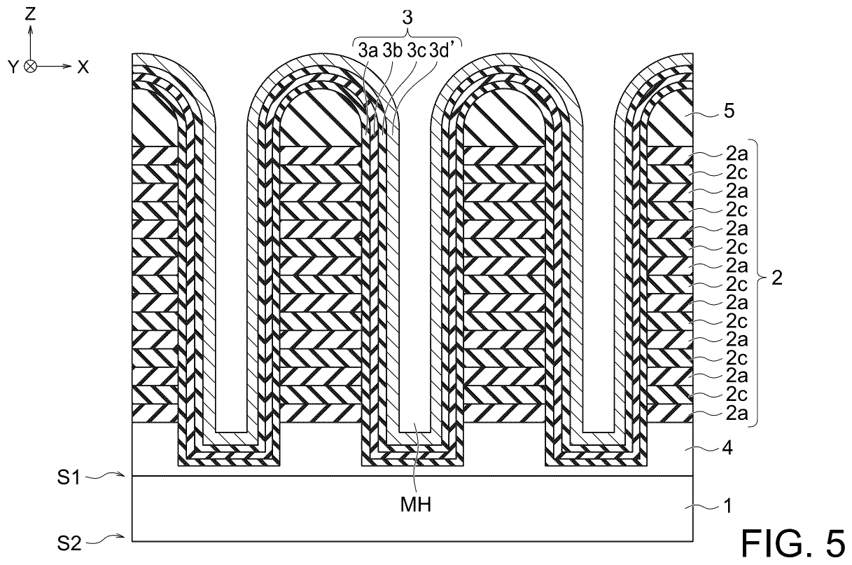

Next, a block insulator 3a, a charge storage layer 3b, a tunnel insulator 3c, and a channel semiconductor layer 3d′ are formed in sequence on the entire surface of the substrate 1 (FIG. 5). As a result, the block insulator 3a, the charge storage layer 3b, the tunnel insulator 3c, and the channel semiconductor layer 3d′ are formed in sequence on the upper face of the underlayer 4 in the memory holes MH, on the side faces of the insulator 5, the stacked film 2, and the underlayer 4 in the memory holes MH, and on the upper face of the insulator 5 outside the memory hole MH. The channel semiconductor layer 3d′ is, for example, an amorphous semiconductor layer such as an amorphous silicon layer. The channel semiconductor layer 3d′ is an example of a semiconductor layer and an amorphous layer.

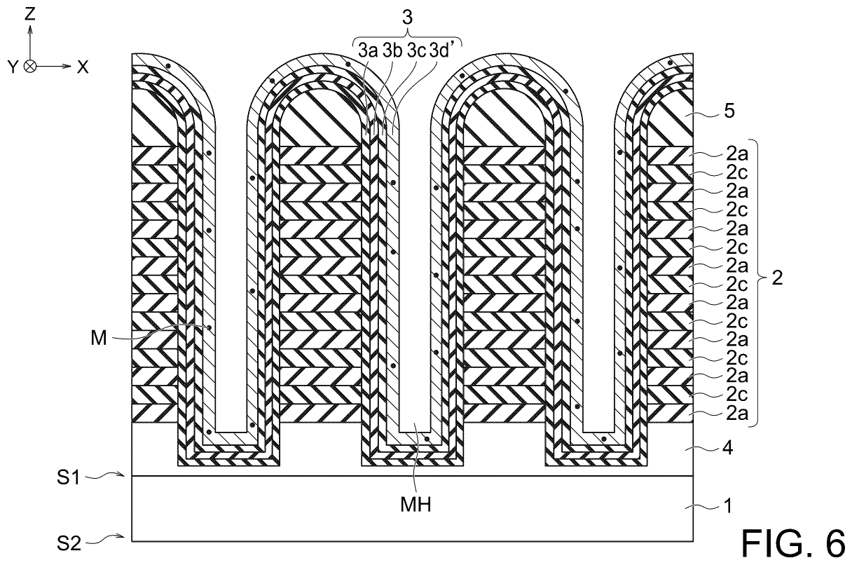

Next, a plurality of metal atoms M are added into the channel semiconductor layer 3d′ (FIG. 6). FIG. 6 shows these metal atoms M in the channel semiconductor layer 3d′ diagrammatically as black dots. These metal atoms M are, for example, Ni (nickel) atoms. Note that instead of being added to the channel semiconductor layer 3d′ in the step of FIG. 6, these metal atoms M may be included in the channel semiconductor layer 3d′ from the point in time when the channel semiconductor layer 3d′ is formed in the step of FIG. 5.

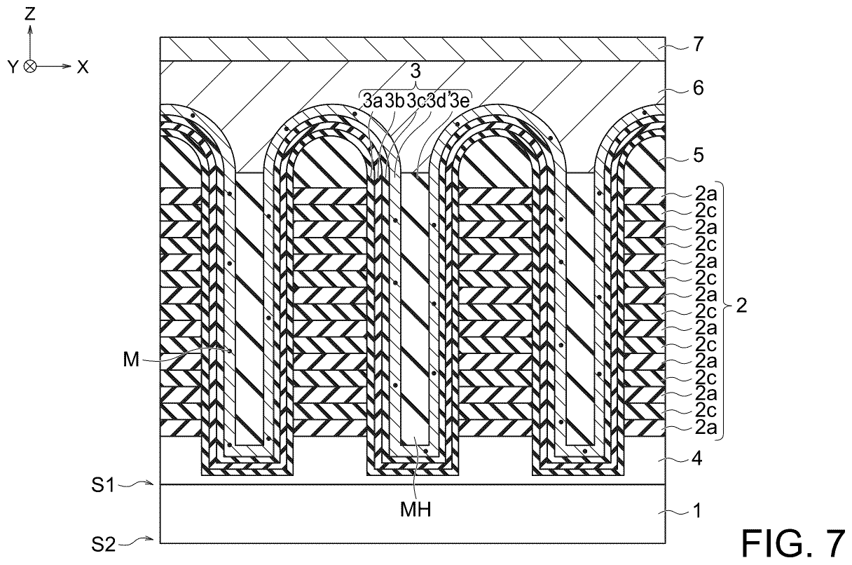

Next, a core insulator 3e is formed in each memory hole MH (FIG. 7). As a result, the core insulator 3e is formed on the side face and upper face of the channel semiconductor layer 3d′ in each memory hole MH. Next, a semiconductor layer 6 is formed on the channel semiconductor layer 3d′ and the core insulator 3e (FIG. 7). As a result, the upper faces of the channel semiconductor layer 3d′ and the core insulator 3e are covered with the semiconductor layer 6. The semiconductor layer 6 is, for example, a Si layer. Next, a getter layer 7 is formed on the semiconductor layer 6 (FIG. 7). The getter layer 7 is, for example, a Si layer doped with N (nitrogen). In this embodiment, the semiconductor layer 6 is in contact with the channel semiconductor layer 3d′, and the getter layer 7 is in contact with the semiconductor layer 6.

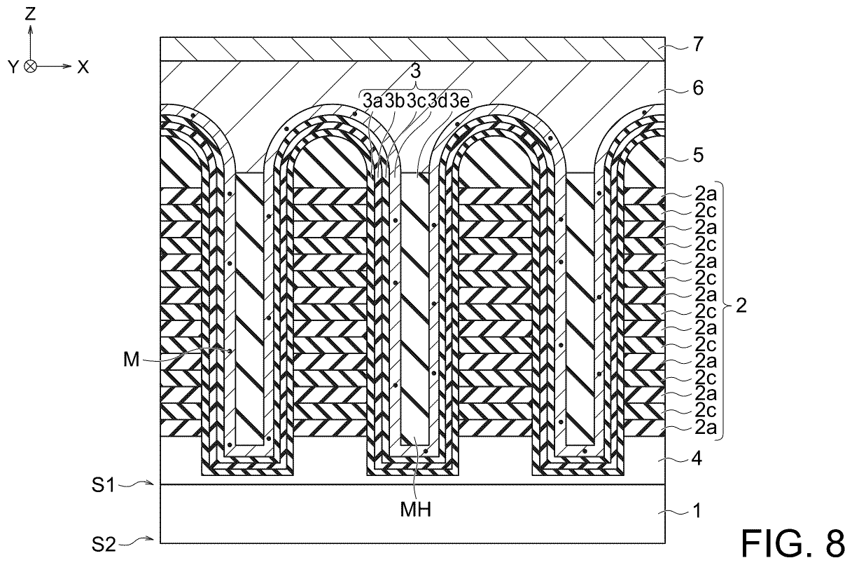

Next, the channel semiconductor layer 3d′ including the metal atoms M is annealed (FIG. 8). As a result, the channel semiconductor layer 3d′ is crystallized and changes into the channel semiconductor layer 3d. The channel semiconductor layer 3d is, for example, a single crystal semiconductor layer such as a single crystal silicon layer. This embodiment makes it possible to anneal the channel semiconductor layer 3d′ including the metal atoms M, thereby increasing the grain size of the crystal grains in the channel semiconductor layer 3d. Note that the channel semiconductor layer 3d may be a polycrystalline semiconductor layer such as a polycrystalline silicon layer.

A technique, in which the channel semiconductor layer 3d′ including metal atoms M is crystallized to form the channel semiconductor layer 3d including crystal grains with a large grain size, is called metal induced crystallization (MIC) or metal induced lateral crystallization (MILC). When the channel semiconductor layer 3d′ is a Si layer and the metal atoms M are Ni atoms, the metal atoms M in the channel semiconductor layer 3d form, for example, NiSi₂ (nickel silicide).

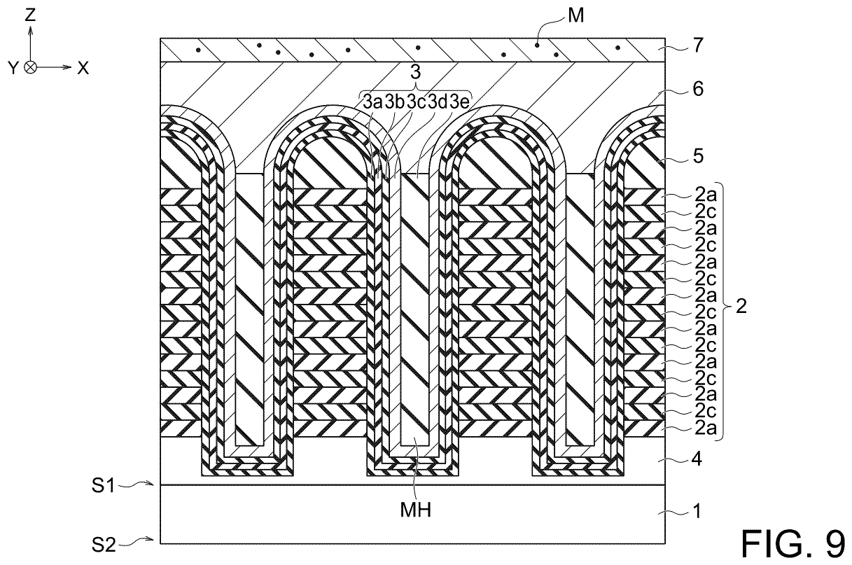

Next, gettering is performed on the channel semiconductor layer 3d (FIG. 9). Gettering is a process for removing metal atoms M from the channel semiconductor layer 3d. FIG. 9 shows the channel semiconductor layer 3d from which the metal atoms M have been removed by gettering. The gettering is performed, for example, by annealing the channel semiconductor layer 3d, the semiconductor layer 6, and the getter layer 7. The metal atoms M in the channel semiconductor layer 3d migrate to the getter layer 7 through the semiconductor layer 6 by this annealing, and are thereby removed from the channel semiconductor layer 3d. Thereafter, part of the metal atoms M in the channel semiconductor layer 3d may remain in the channel semiconductor layer 3d also after gettering.

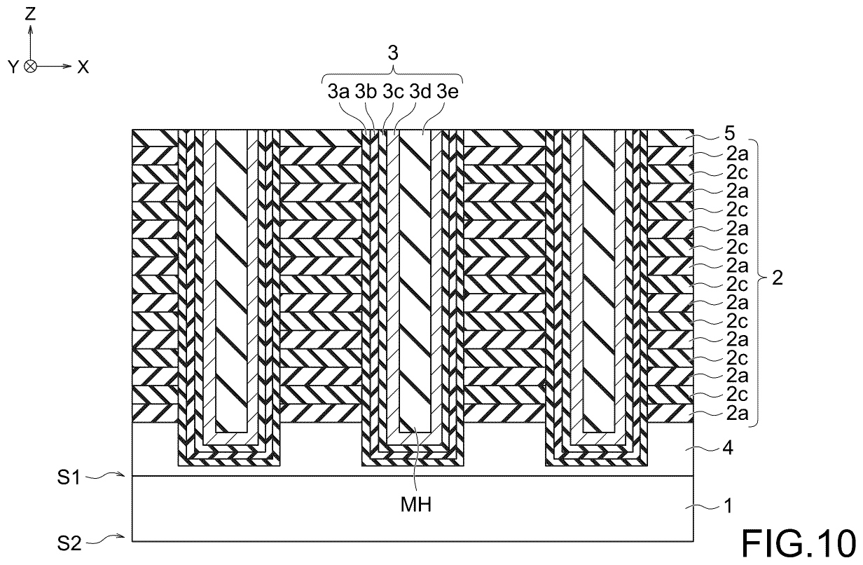

Next, the surface of the getter layer 7 is planarized by chemical mechanical polishing (CMP) (FIG. 10). As a result, the getter layer 7 is removed, and further the semiconductor layer 6, a portion of the insulator 5, as well as the block insulator 3a, the charge storage layer 3b, the tunnel insulator 3c, and the channel semiconductor layer 3d that are located outside the memory hole MH are removed. In this manner, each columnar portion 3 is formed in a corresponding one of the memory holes MH.

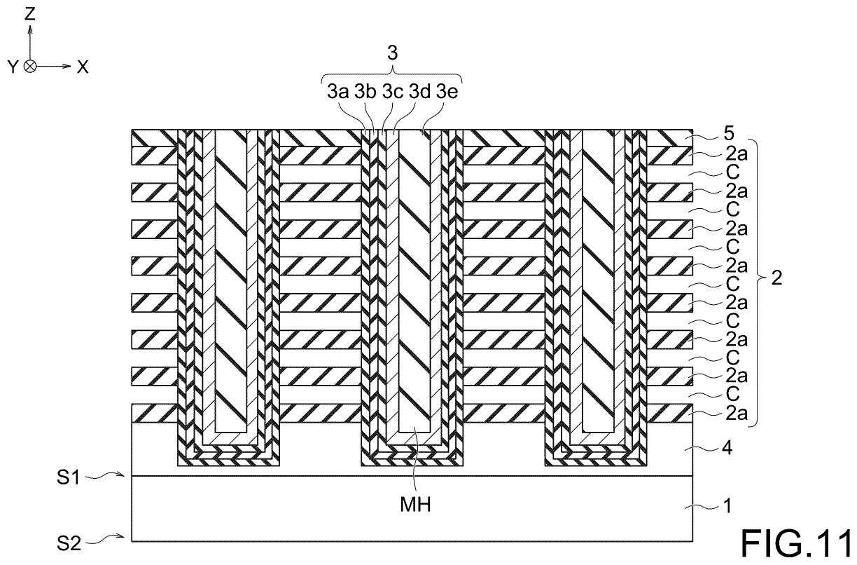

Next, a plurality of slits (not shown) are formed in the insulator 5, the stacked film 2, and the underlayer 4 by lithography and RIE, and the sacrificial layers 2c are removed by wet etching from the slits (FIG. 11). As a result, a plurality of cavities C are formed in the stacked film 2.

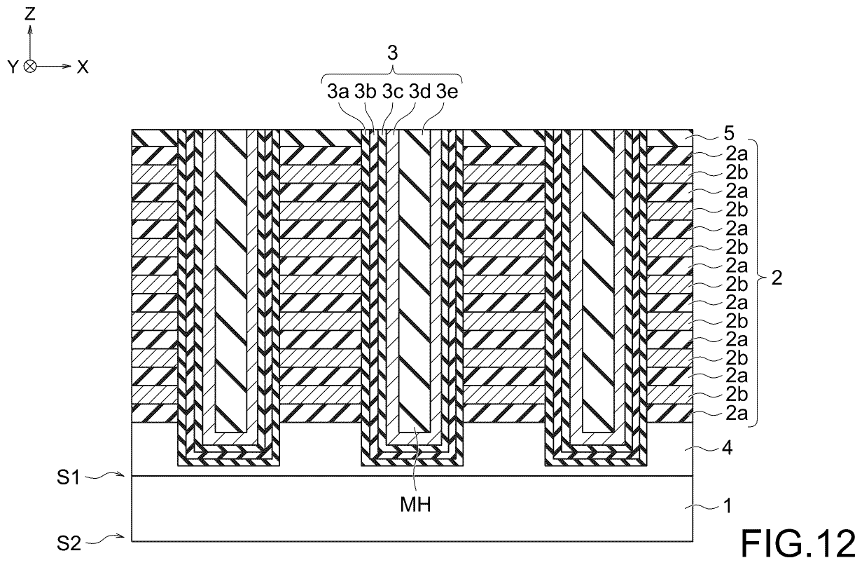

Next, a plurality of electrode layers 2b are formed in these cavities C (FIG. 12). As a result, a stacked film 2 including a plurality of insulators 2a and a plurality of electrode layers 2b alternately provided in the Z direction is formed on the underlayer 4. In this manner, the sacrificial layers 2c are replaced with the electrode layers 2b, and the semiconductor device shown in FIG. 1 is manufactured.

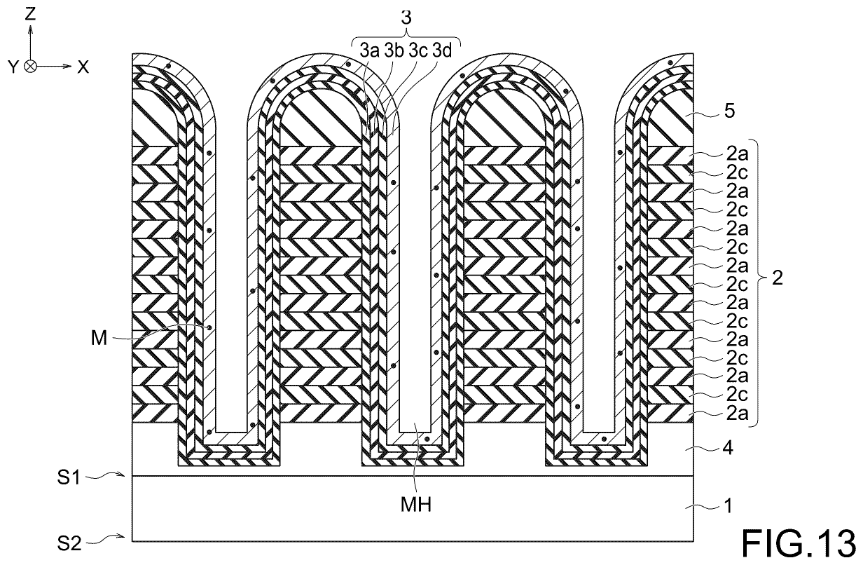

FIGS. 13 to 15 are cross-sectional views showing a method of manufacturing a semiconductor device of a modification of the first embodiment.

First, the steps of FIGS. 3 to 6 are performed, and then the channel semiconductor layer 3d′ including metal atoms M is annealed (FIG. 13). As a result, the channel semiconductor layer 3d′ is crystallized and changes into the channel semiconductor layer 3d. The annealing in FIG. 13 is performed similarly to the annealing in FIG. 8. However, the annealing in FIG. 13 is performed in a state in which the core insulator 3e, the semiconductor layer 6, and the getter layer 7 are not yet formed on the channel semiconductor layer 3d′.

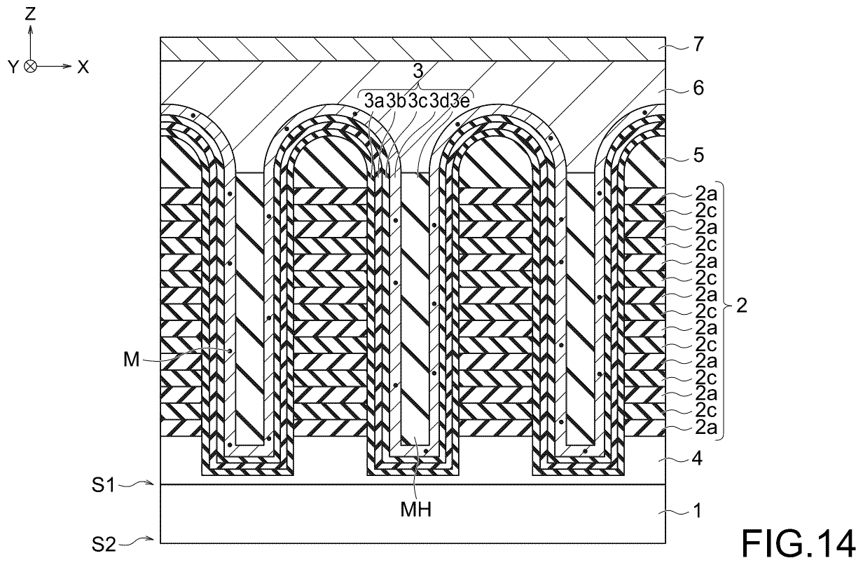

Next, a core insulator 3e is formed in each memory hole MH, a semiconductor layer 6 is formed on the channel semiconductor layer 3d′ and the core insulator 3e, and a getter layer 7 is formed on the semiconductor layer 6 (FIG. 14). The step of FIG. 14 is performed in the same manner as the step of FIG. 7.

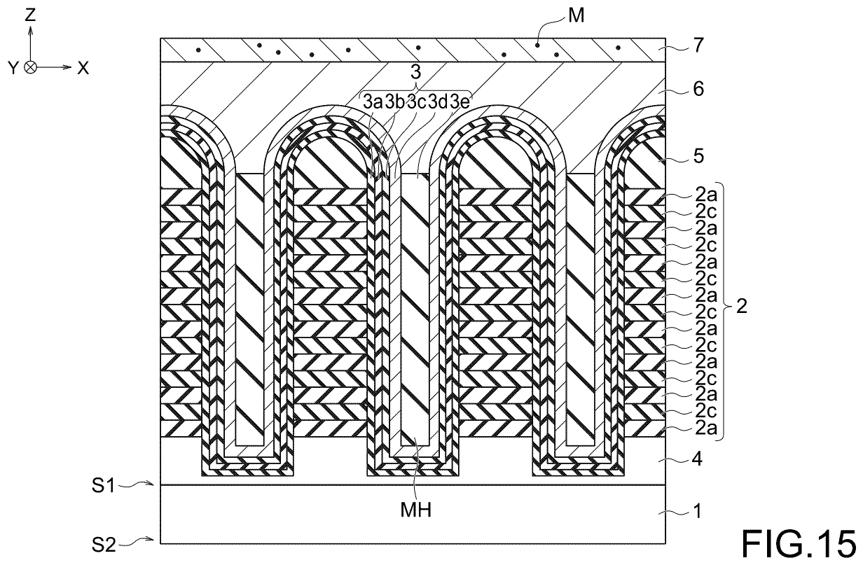

Next, gettering is performed on the channel semiconductor layer 3d (FIG. 15). FIG. 15 shows the channel semiconductor layer 3d from which the metal atoms M have been removed by gettering. The gettering in FIG. 15 is performed in the same manner as the gettering in FIG. 9.

Thereafter, the steps of FIG. 10 to FIG. 12 are performed. In this manner, the semiconductor device shown in FIG. 1 is manufactured.

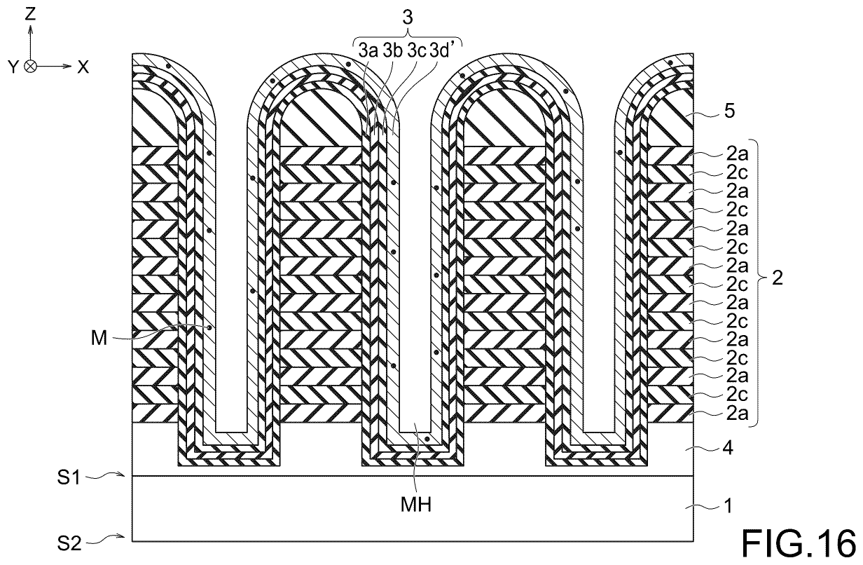

Various examples of the crystal evaluation method of this embodiment is described below with reference to FIGS. 16 to 38. The crystal evaluation method of this embodiment is, for example, producing a semiconductor device having a structure similar to that of the semiconductor device shown in FIG. 1 before manufacturing the semiconductor device shown in FIG. 1, and evaluating the crystallinity of a channel semiconductor layer in the produced semiconductor device. In this case, it is not necessary to produce a completed semiconductor device, and the crystallinity of the channel semiconductor layer in the semiconductor device before completion may be evaluated. This embodiment makes it possible to evaluate the crystallinity of the channel semiconductor layer to improve the semiconductor device shown in FIG. 1 and the method of manufacturing the device, and makes it possible to manufacture the semiconductor device including a channel semiconductor layer having good crystallinity. The description of FIGS. 16 to 38 uses the same reference numerals and characters as those used in FIGS. 1 to 15.

### (1) First Example

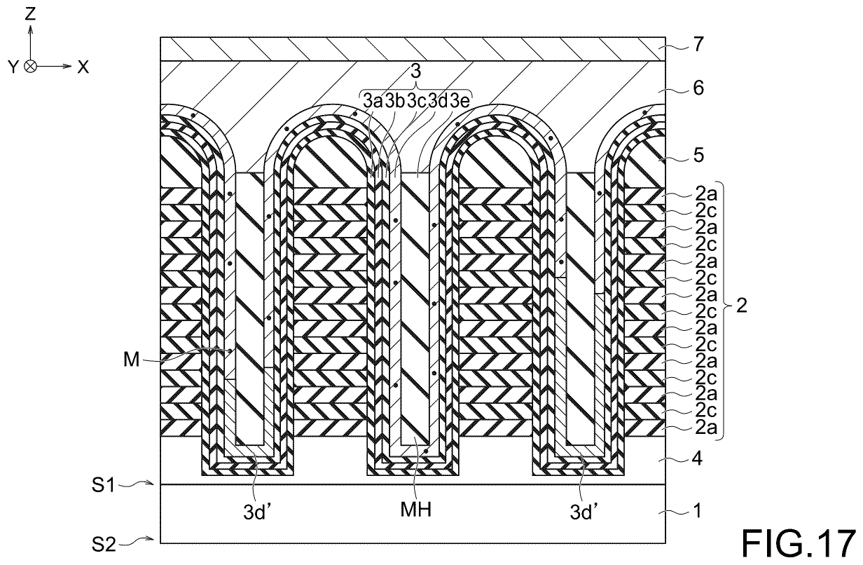

FIGS. 16 and 17 are cross-sectional views showing a first example of the crystal evaluation method of the first embodiment.

First, the steps of FIGS. 3 to 6 are performed (FIG. 16). As a result, as shown in FIG. 16, a plurality of metal atoms M are added into the channel semiconductor layer 3d′. The channel semiconductor layer 3d′ is, for example, an amorphous silicon layer.

However, the channel semiconductor layer 3d′ shown in FIG. 16 includes a region including metal atoms M and regions not including metal atoms M. This is presumably because the metal atoms M has not been appropriately added to the channel semiconductor layer 3d′ for some reason. In FIG. 16, the channel semiconductor layer 3d′ includes metal atoms M at the lower end of the central columnar portion 3, but the channel semiconductor layer 3d′ does not include metal atoms M at the lower end of the right columnar portion 3 or the lower end of the left columnar portion 3. This is presumably because when the metal atoms M are added into the channel semiconductor layer 3d′, the metal atoms M have not reached the lower end of the right columnar portion 3 or the lower end of the left columnar portion 3.

Next, the steps of FIGS. 7 and 8 are performed (FIG. 17). As a result, the channel semiconductor layer 3d′ is crystallized and changes into the channel semiconductor layer 3d as shown in FIG. 17. The channel semiconductor layer 3d is, for example, a single crystal semiconductor layer or a polycrystalline silicon layer.

However, in FIG. 17, only a portion of the channel semiconductor layer 3d′ is crystallized and changes into the channel semiconductor layer 3d. The remaining portion of the channel semiconductor layer 3d′ is not crystallized and remains as the channel semiconductor layer 3d′. This is presumably because the absence of metal atoms M did not promote crystallization in the region not including metal atoms M in the channel semiconductor layer 3d′. In FIG. 17, at the lower end of the central columnar portion 3, the channel semiconductor layer 3d′ changes into the channel semiconductor layer 3d, but at the lower end of the right columnar portion 3 and the lower end of the left columnar portion 3, the channel semiconductor layer 3d′ does not change into the channel semiconductor layer 3d.

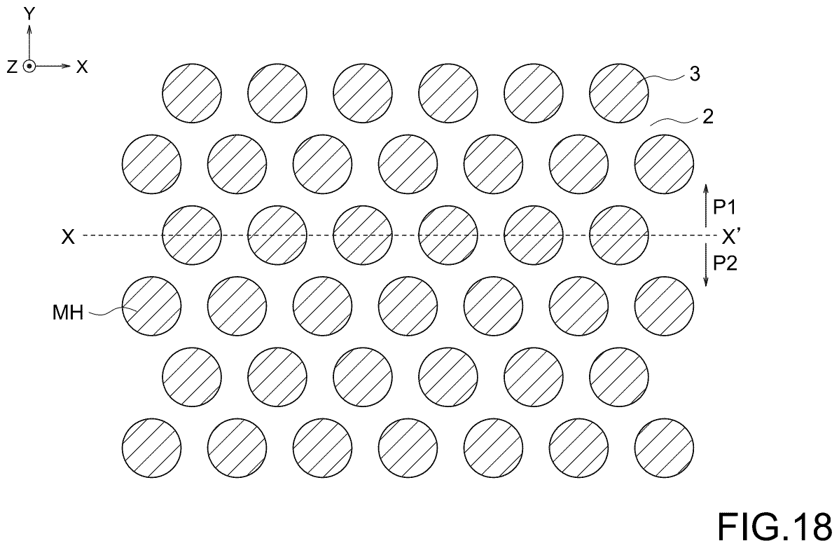

FIG. 18 is a plan view showing the first example of the crystal evaluation method of the first embodiment.

FIG. 18 is a plan view corresponding to the cross-sectional view of FIG. 17. In this embodiment, after the step of FIG. 17 is performed, the gettering of FIG. 9 is performed. Thereafter, the substrate 1, the stacked film 2, the columnar portions 3, and the like are cleaved along line X-X′ shown in FIG. 18. As a result, the substrate 1, the stacked film 2, the columnar portions 3, and the like are divided into a portion P1 and a portion P2 shown in FIG. 18. This makes it possible to observe the vertical cross section (XZ cross section) of the substrate 1, the stacked film 2, the columnar portions 3, and the like.

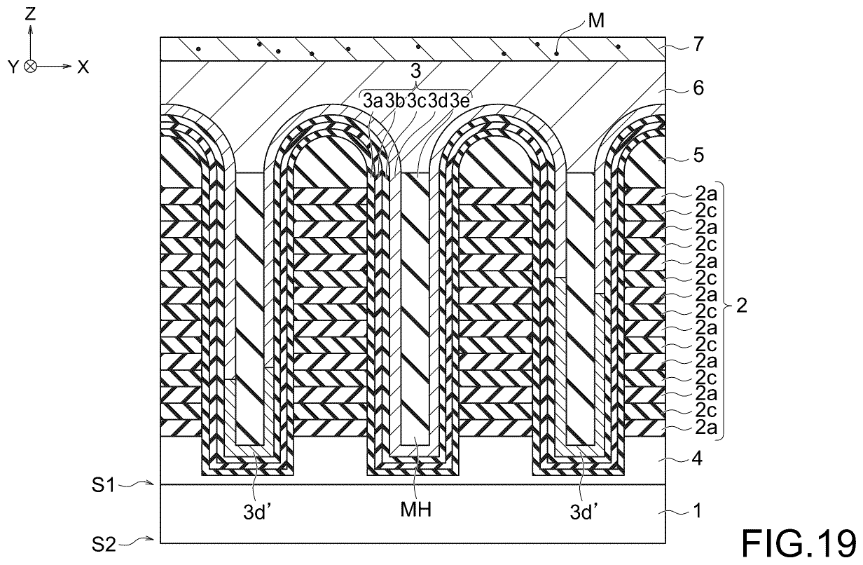

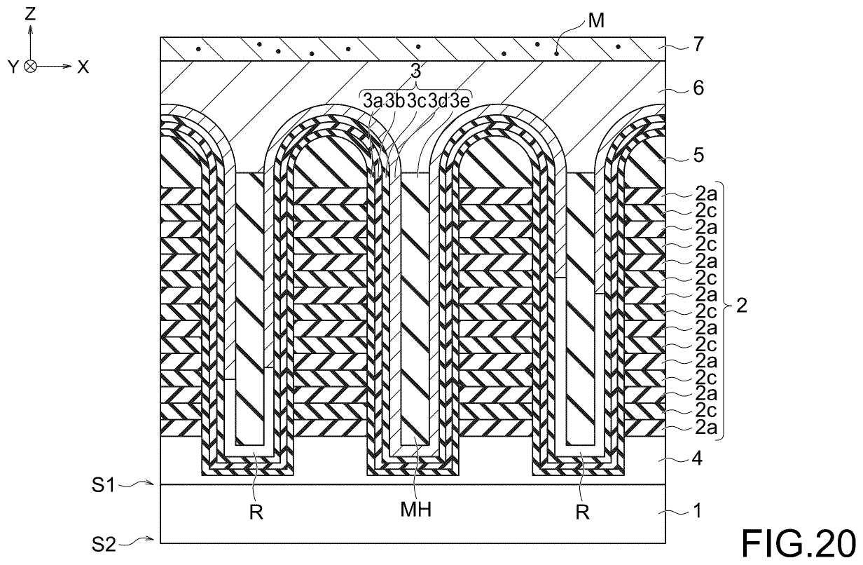

FIGS. 19 and 20 are cross-sectional views showing the first example of the crystal evaluation method of the first embodiment.

FIG. 19 shows the cleavage plane of portion P1, that is, a vertical cross section of the substrate 1, the stacked film 2, the columnar portions 3, and the like. FIG. 19 shows a channel semiconductor layer 3d from which metal atoms M have been removed by gettering, and a channel semiconductor layer 3d′ that has not changed into the channel semiconductor layer 3d.

Next, the channel semiconductor layers 3d, 3d′ are treated with a chemical liquid (FIG. 20). Specifically, a chemical liquid is supplied to the channel semiconductor layers 3d, 3d′ exposed on the vertical cross section of the stacked film 2 and the like. The chemical liquid used in FIG. 20 is an etching solution that dissolves the channel semiconductor layer 3d′. At this time, the channel semiconductor layer 3d′ may be crystallized from an amorphous silicon layer to a silicon layer having a small grain size by the above-described gettering. Also in this case, the channel semiconductor layer 3d′, which is a silicon layer having a small grain size, can be selectively etched by the above-described chemical liquid. Therefore, in the step of FIG. 20, the channel semiconductor layer 3d′ of the channel semiconductor layers 3d, 3d′ is selectively removed by etching. FIG. 20 shows two cavities R formed in two memory holes MH by removing the channel semiconductor layer 3d′, and the channel semiconductor layer 3d remaining after etching. In FIG. 20, a portion of the channel semiconductor layer 3d in the channel semiconductor layers 3d, 3d′ is an example of a first portion, and a portion of the channel semiconductor layer 3d′ in the channel semiconductor layers 3d, 3d′ is an example of a second portion.

In the step of FIG. 20, two types of liquids are used as the chemical liquids. The two types of liquids are, for example, a dilute hydrofluoric acid aqueous solution and a mixed acid solution including hydrofluoric acid, nitric acid, and acetic acid. This makes it possible to selectively etch silicon having a small grain size, and therefore to selectively remove the channel semiconductor layer 3d′. The mixed acid solution includes, for example, 5 to 10% hydrofluoric acid, 20 to 50% nitric acid, and the remaining % acetic acid.

In the step of FIG. 20, first, a dilute hydrofluoric acid aqueous solution is supplied to the channel semiconductor layers 3d, 3d′, and then a mixed acid solution is supplied to the channel semiconductor layers 3d, 3d′. As a result, the channel semiconductor layer 3d′ is removed, and the region of the channel semiconductor layer 3d in each memory hole MH is elicited. This treatment is called an elicitation treatment, and the mixed acid solution is called an elicitation liquid. Here, when a chemical liquid including hydrofluoric acid, such as a dilute hydrofluoric acid aqueous solution or a mixed acid solution, is supplied to the channel semiconductor layers 3d, 3d′, the core insulator 3e may also be removed by the chemical liquid.

This embodiment (first example) makes it possible to treat the channel semiconductor layers 3d, 3d′ with a chemical liquid to determine the crystallization state of the channel semiconductor layer (channel semiconductor layers 3d, 3d′) in each memory hole MH. For example, it is possible to determine whether the channel semiconductor layer in each memory hole MH includes only the channel semiconductor layer 3d or includes the channel semiconductor layers 3d, 3d′. When the number of memory holes MH to be evaluated is “N”, and among these “N” memory holes MH, the number of memory holes MH that include only the channel semiconductor layer 3d is “K”, the value of “K/N” is called the crystallization rate. In this embodiment, the crystallization state may be determined by detecting the crystallization state of the channel semiconductor layer in a plurality of memory holes MH and calculating the crystallization rate of the channel semiconductor layer in these memory holes MH. Note that when there are memory holes MH including only the channel semiconductor layer 3d′, the number of memory holes MH including only the channel semiconductor layer 3d′ is not included in the value of K, just like the number of memory holes MH including the channel semiconductor layers 3d, 3d′.

In this embodiment, after treating the channel semiconductor layers 3d, 3d′ with a chemical liquid, the vertical cross sections of the stacked film 2 and the columnar portions 3 are imaged, and the image obtained by imaging is used to determine the crystallization state of the channel semiconductor layer in each memory hole MH. For example, observation of the image determines whether the channel semiconductor layer in each memory hole MH includes only the channel semiconductor layer 3d or includes the channel semiconductor layers 3d, 3d′. For calculating the above-described crystallization rate, the number of memory holes MH included in the image may be set as the value of N. The image is taken, for example, by a scanning electron microscope (SEM) or an optical microscope. Alternatively, there may be a method of acquiring a profile of the vertical cross section of the stacked film 2 and the columnar portions 3 after treating the channel semiconductor layers 3d, 3d′ with a chemical liquid, and using the acquired profile to determine the crystallization state of the channel semiconductor layer in each memory hole MH. The profile is acquired, for example, by small-angle X-ray scattering (SAXS).

When the vertical cross section of the stacked film 2 shown in FIG. 20 is imaged, the image or profile demonstrates that the channel semiconductor layer in the central memory hole MH does not include a cavity R, and the channel semiconductor layers in the right and left memory holes MH each include a cavity R. Thus, it can be determined that, within the stacked film 2 before etching with the chemical liquid, the channel semiconductor layer in the central memory hole MH has included only the channel semiconductor layer 3d, and the channel semiconductor layers in the right and left memory holes MH each have included the channel semiconductor layers 3d, 3d′.

In this embodiment, if the crystallization rate is not 100%, various conditions in the steps of FIGS. 16 and 17 may be adjusted to make the crystallization rate 100%. For example, the Ni concentration in the channel semiconductor layer 3d′ or the annealing temperature of the channel semiconductor layer 3d′ may be adjusted. This makes it possible to reduce the problem in which the channel semiconductor layer 3d′ remains after annealing of the channel semiconductor layer 3d′.

In the first example, when the channel semiconductor layer 3d is formed from the channel semiconductor layer 3d′ using the metal atoms M, the crystallization state is determined after the metal atoms M are removed. In other words, when the channel semiconductor layer 3d is formed by MIC or MILC, the crystallization state is determined after gettering. This makes it possible to prevent the metal atoms M from adversely affecting the chemical liquid to be used for the determination.

On the other hand, in this embodiment, the crystal evaluation method may be carried out by employing a second example or a third example described below instead of the first example. Regarding the second and third examples, differences from the first example are mainly described, and description of commonalities with the first example is omitted as appropriate.

### (2) Second Example

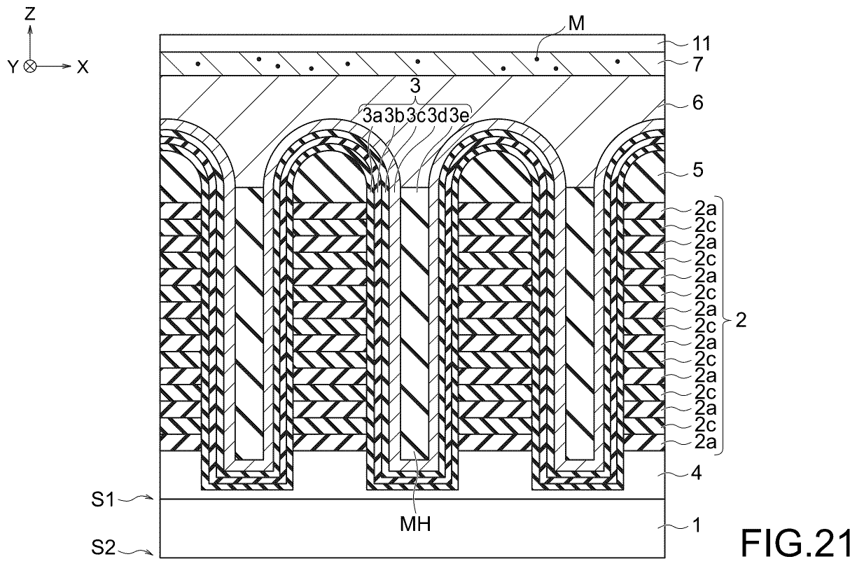

FIGS. 21 to 25 are cross-sectional views showing a second example of the crystal evaluation method of the first embodiment.

First, the steps of FIGS. 3 to 9 are performed (FIG. 21). FIG. 21 shows the channel semiconductor layer 3d from which the metal atoms M have been removed by the gettering in FIG. 9. FIG. 21, like FIG. 9, shows the channel semiconductor layer 3d when all portion of the channel semiconductor layer 3d′ have changed into the channel semiconductor layer 3d. On the other hand, the case is described below in which only a portion of the channel semiconductor layer 3d′ has changed into the channel semiconductor layer 3d.

Next, the underlayer 11 is formed on the getter layer 7, and then the surface of the underlayer 11 is planarized by CMP (FIG. 21). The underlayer 11 is, for example, a SiO₂ film or a SiCN film (silicon carbonitride film). The underlayer 11 may be an insulator or may be a material other than an insulator.

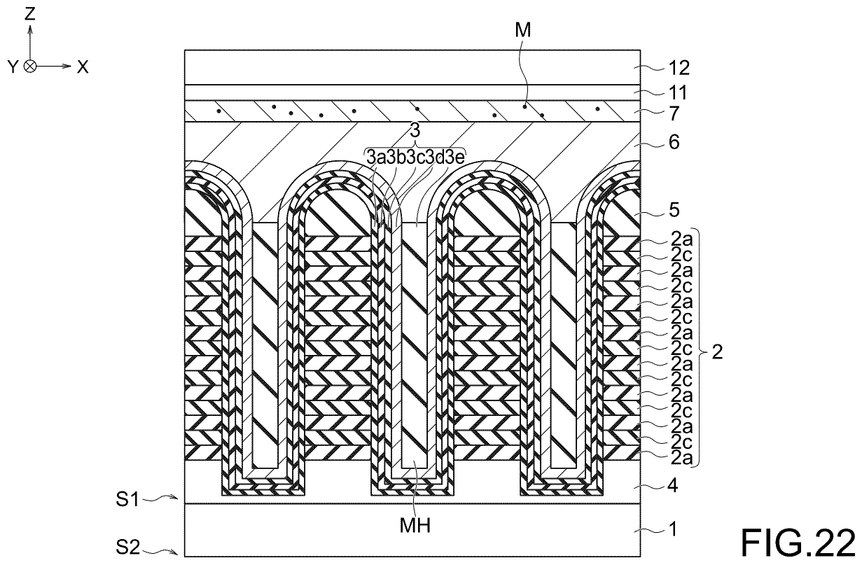

Next, the substrate 1 and the support substrate 12 are bonded so as to sandwich the underlayer 4, the stacked film 2, the semiconductor layer 6, the getter layer 7, the underlayer 11, and the like (FIG. 22). As a result, the support substrate 12 is placed on the underlayer 11. The support substrate 12 is, for example, a Si substrate. The support substrate 12 may be a semiconductor substrate or a substrate other than a semiconductor substrate. The support substrate 12 is an example of a second substrate.

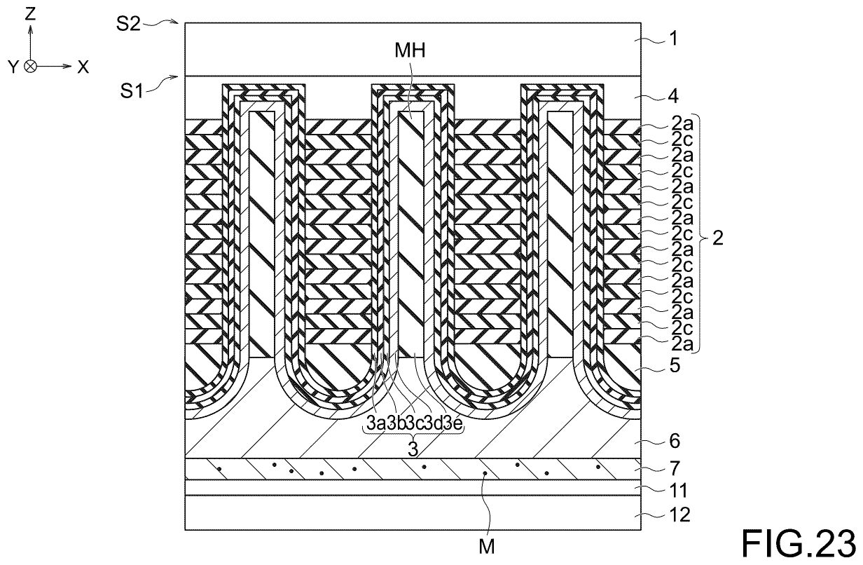

The underlayer 11 is formed to bond the support substrate 12 to the substrate 1. In the step of FIG. 22, the lower face of the support substrate 12 is brought into contact with the upper face of the underlayer 11, and then the underlayer 11, the support substrate 12, and the like are annealed. As a result, the support substrate 12 is bonded to the underlayer 11 and the support substrate 12 is bonded to the substrate 1. FIG. 23 shows the substrate 1, the support substrate 12, and the like, upside down from the state shown in FIG. 22.

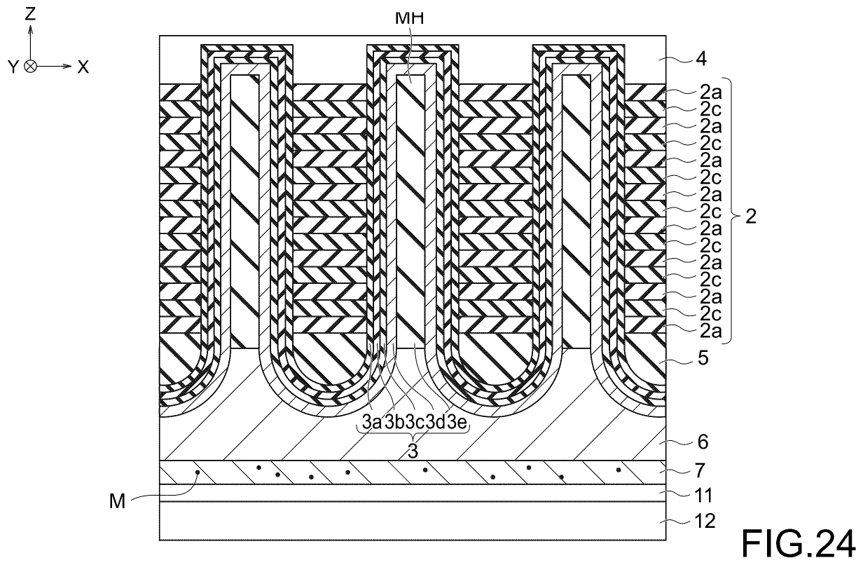

Next, the substrate 1 is removed by backgrinding (FIG. 24). As a result, the upper face of the underlayer 4 is exposed above the support substrate 12. In this manner, the substrate 1 is removed so that the underlayer 11, the getter layer 7, the semiconductor layer 6, the stacked film 2, the underlayer 4, and the like remain on the support substrate 12. The substrate 1 may be removed by a combination of backgrinding and CMP.

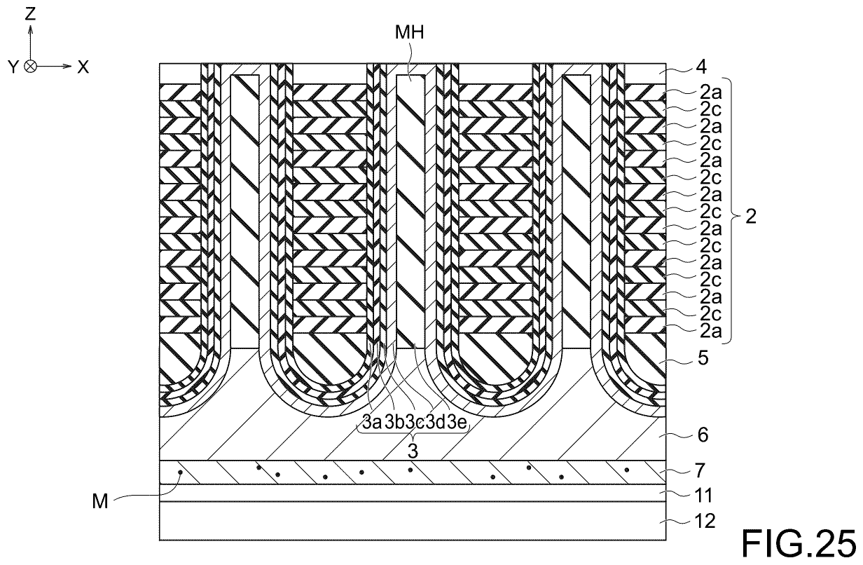

Next, the upper face of the underlayer 4 is planarized by CMP (FIG. 25). As a result, the underlayer 4 is thinned, and further, the block insulator 3a, the charge storage layer 3b, and the tunnel insulator 3c on the bottom face of each memory hole MH are removed. As a result, above the support substrate 12, the channel semiconductor layer 3d at the bottom of each memory hole MH is exposed from the upper face of the underlayer 4. The block insulator 3a, the charge storage layer 3b, and the tunnel insulator 3c on the bottom face of each memory hole MH may be removed by wet etching or chemical dry etching (CDE). The wet etching is performed using a chemical liquid such as hydrofluoric acid or phosphoric acid.

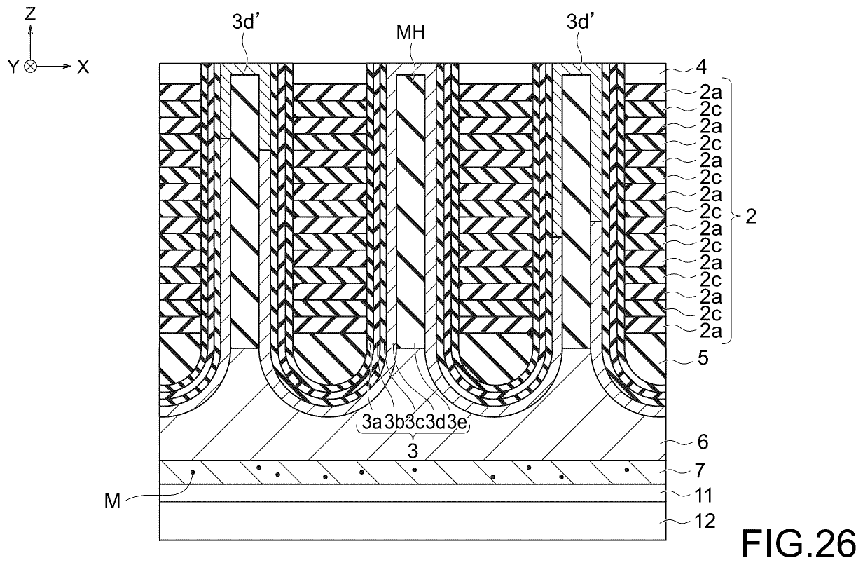

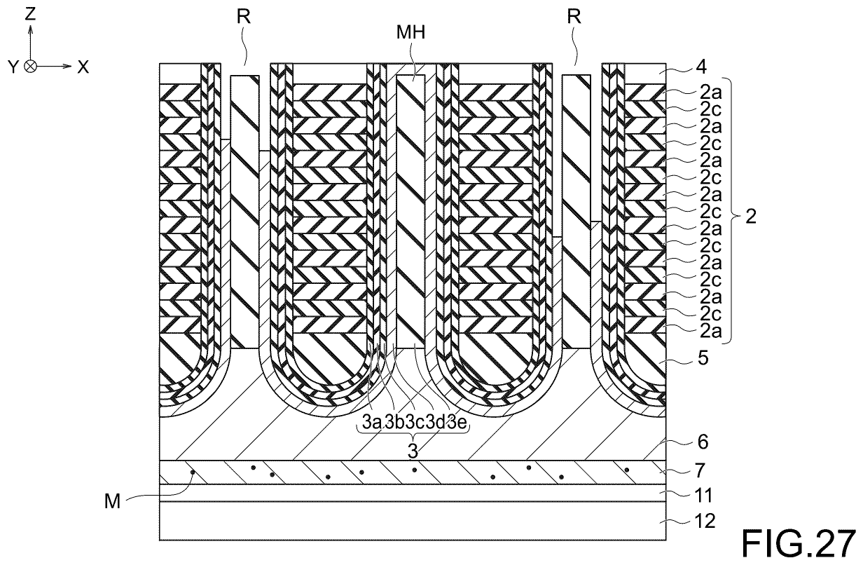

FIGS. 26 and 27 are cross-sectional views showing the second example of the crystal evaluation method of the first embodiment.

FIG. 26, like FIG. 25, shows the underlayer 4, the channel semiconductor layer 3d, and the like after the steps of FIGS. 21 to 25 have been performed. However, like FIGS. 17 and 19, FIG. 26 shows the channel semiconductor layers 3d, 3d′ when only a portion of the channel semiconductor layer 3d′ has changed into the channel semiconductor layer 3d. FIG. 26, like FIG. 19, shows the channel semiconductor layers 3d, 3d′ after gettering, and therefore the channel semiconductor layer 3d shown in FIG. 26 does not include metal atoms M.

Next, the channel semiconductor layers 3d, 3d′ are treated with a chemical liquid (FIG. 27). Specifically, a chemical liquid is supplied to the channel semiconductor layers 3d, 3d′ exposed on the upper face of the underlayer 4 above the support substrate 12. The chemical liquid used in FIG. 27 is an etching solution that dissolves the channel semiconductor layer 3d′, like the chemical liquid used in FIG. 20. Therefore, in the step of FIG. 27, the channel semiconductor layer 3d′ of the channel semiconductor layers 3d, 3d′ is selectively removed by etching. FIG. 27 shows two cavities R formed in two memory holes MH by removing the channel semiconductor layer 3d′, and the channel semiconductor layer 3d remaining after etching.

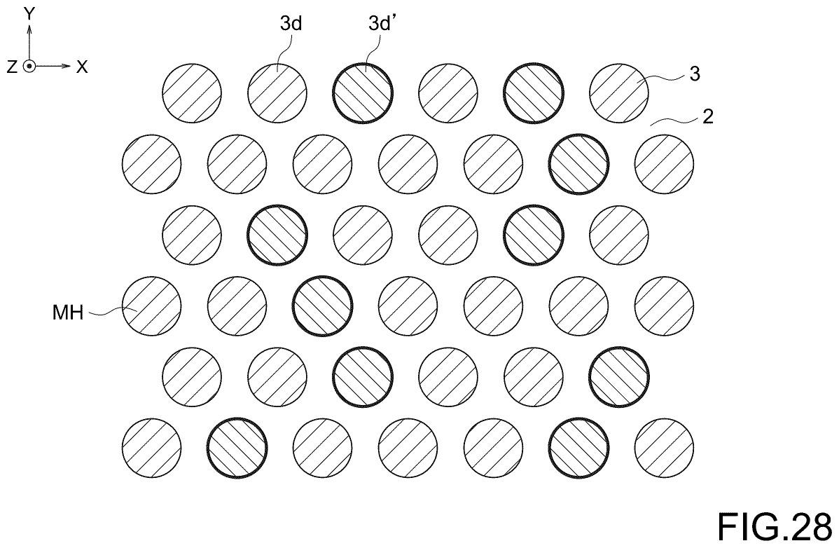

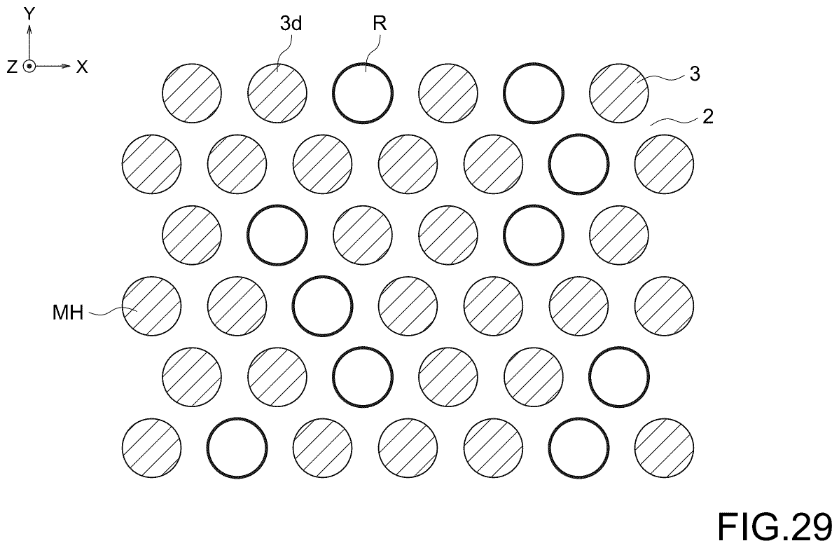

FIGS. 28 and 29 are plan views showing the second example of the crystal evaluation method of the first embodiment.

FIG. 28 is a plan view corresponding to the cross-sectional view of FIG. 26. For ease of understanding, FIG. 28 illustrates the memory holes MH (columnar portions 3) including the channel semiconductor layer 3d′ with a bold outline.

On the other hand, FIG. 29 is a plan view corresponding to the cross-sectional view of FIG. 27. FIG. 29 shows ten cavities R formed in ten memory holes MH by removing the channel semiconductor layer 3d′.

According to this embodiment (second example), like the first example, treating the channel semiconductor layers 3d, 3d′ with a chemical liquid makes it possible to determine the crystallization state of the channel semiconductor layer (channel semiconductor layers 3d, 3d′) in each memory hole MH. The crystallization rate, imaging, profile acquisition, and the like in the second example are similar to those in the first example. However, in the second example, the underlayer 4 and the upper face of the columnar portion 3 are imaged. For example, when the image obtained by imaging includes 39 memory holes MH shown in FIG. 29, the crystallization rate is 29/39. The same applies to profile acquisition.

In the first example, in order to determine the crystallization state, it is necessary to cleave the substrate 1, the stacked film 2, the columnar portions 3, and the like. In this case, problems arise in which labor is required and appropriate cleavage is difficult. For example, if cleavage is performed at a cross section that does not pass through the channel semiconductor layers 3d, 3d′, the crystallization state cannot be determined. In contrast, in the second example, since the chemical liquid is supplied to the channel semiconductor layers 3d, 3d′ exposed on the upper face of the underlayer 4, the crystallization state can be determined without cleavage. This makes it possible to prevent problems associated with cleavage.

Generally, only a small number of columnar portions 3 are exposed in the vertical cross section of the stacked film 2, but a large number of columnar portions 3 are exposed on the upper face of the underlayer 4. Therefore, the second example makes it possible to evaluate many columnar portions 3 simultaneously.

In the annealing of FIG. 8, the channel semiconductor layer 3d′ is likely to remain near the bottom face of each memory hole MH. The reason is that when metal atoms M are added into the channel semiconductor layer 3d′ in FIG. 6, the metal atoms M have difficulty reaching near the bottom face of each memory hole MH. In the second example, a chemical liquid is supplied to the channel semiconductor layers 3d, 3d′ near the bottom face of each memory hole MH where the channel semiconductor layer 3d′ is likely to remain. This makes it possible to reduce detection failure of the channel semiconductor layer 3d′.

Note that each memory hole MH may be formed in the step of FIG. 4 so as to have a bottom face in the substrate 1. In this case, in the steps of FIGS. 24 and 25, the substrate 1 may be thinned so that the channel semiconductor layer 3d (or the channel semiconductor layer 3d′) at the bottom face of each memory hole MH is exposed from the upper face of the substrate 1. In this case, there is no need to remove the substrate 1 or thin the underlayer 4, and the chemical liquid is supplied to the channel semiconductor layers 3d, 3d′ exposed on the upper face of the substrate 1.

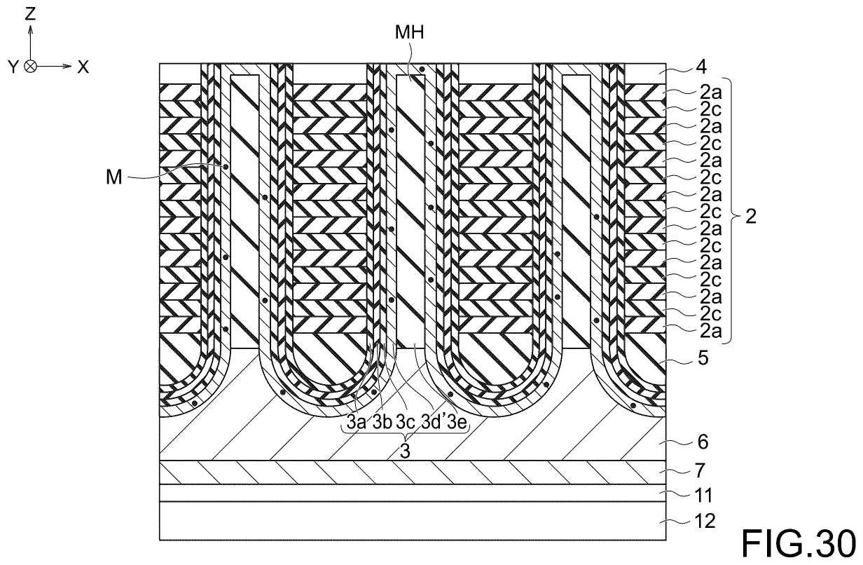

Below, a modification of the processes shown in FIGS. 26 to 29 is described with reference to FIGS. 30 to 34.

FIGS. 30 to 32 are cross-sectional views showing the modification of the second example of the crystal evaluation method of the first embodiment.

FIG. 30, like FIGS. 25 and 26, shows the underlayer 4 and the like after the steps of FIGS. 21 to 25 have been performed. However, FIG. 30 shows the underlayer 4 and the like when the underlayer 11 is formed after the steps of FIGS. 3 to 7. Therefore, FIG. 30 shows the channel semiconductor layer 3d′ before performing the annealing in FIG. 8 or the gettering in FIG. 9. The channel semiconductor layer 3d′ shown in FIG. 30 includes a region including metal atoms M and regions not including metal atoms M, like the channel semiconductor layer 3d′ shown in FIG. 16. In FIG. 30, the getter layer 7 does not necessarily have to be formed.

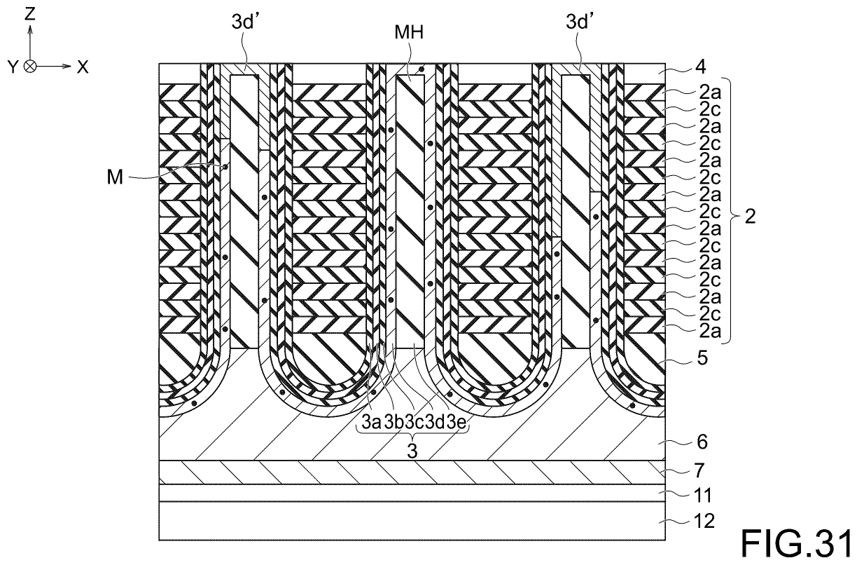

Next, the annealing of FIG. 8 is performed (FIG. 31). As a result, a portion of the channel semiconductor layer 3d′ is crystallized and changes into the channel semiconductor layer 3d. The remaining portion of the channel semiconductor layer 3d′ is not crystallized and remains as the channel semiconductor layer 3d′. Note that the annealing may be performed before the underlayer 11 is formed, that is, may be performed in the step of FIG. 21.

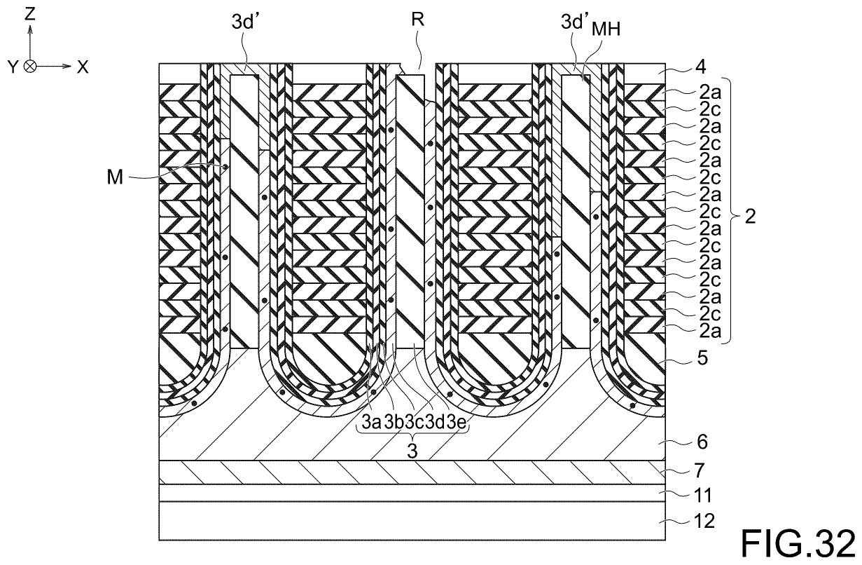

Next, the channel semiconductor layers 3d, 3d′ are treated with a chemical liquid (FIG. 32). Specifically, a chemical liquid is supplied to the channel semiconductor layers 3d, 3d′ exposed on the upper face of the underlayer 4 above the support substrate 12. The chemical liquid used in FIG. 32 is an etching solution that dissolves metal silicide such as NiSi₂. Therefore, in the step of FIG. 32, a portion of the channel semiconductor layer 3d of the channel semiconductor layers 3d, 3d′ is selectively removed by etching. Specifically, the channel semiconductor layer 3d includes one or more NiSi₂ regions (regions including NiSi₂), and the NiSi₂ regions exposed on the upper face of the channel semiconductor layer 3d are removed by etching. FIG. 32 diagrammatically shows a cavity R formed in the channel semiconductor layer 3d by removing the NiSi₂ regions, and the channel semiconductor layers 3d, 3d′ remaining after etching. In observation of the underlayer 4 shown in FIG. 32 from the +Z direction, the channel semiconductor layer 3d′ remains in the right and left memory holes MH, but a cavity R is formed in the channel semiconductor layer 3d in the central memory hole MH. Note that only a portion of the channel semiconductor layer 3d is removed in FIG. 32, but the entire channel semiconductor layer 3d may be removed. The crystal evaluation method of this embodiment can be applied to both the case in which the channel semiconductor layer 3d is partially removed and the case in which the channel semiconductor layer 3d is completely removed.

In the step of FIG. 32, one type of liquid is used as the chemical liquid. The one type of liquid is, for example, a dilute hydrofluoric acid aqueous solution, SC2, NC2, or SC1. This makes it possible to selectively etch NiSi₂, and therefore to selectively remove the NiSi₂ region exposed on the upper face of the channel semiconductor layer 3d. Therefore, in the step of FIG. 32, in a state in which the channel semiconductor layer 3d includes metal atoms M, a chemical liquid is supplied to the channel semiconductor layers 3d and 3d′. In other words, before the gettering in FIG. 9 is performed, a chemical liquid is supplied to the channel semiconductor layers 3d and 3d′. Note that the concentration of HF (hydrogen fluoride) in the dilute hydrofluoric acid aqueous solution is, for example, about 1%. SC2 is an aqueous solution including hydrochloric acid and hydrogen peroxide. NC2 is an aqueous solution including choline and hydrogen peroxide. SC1 is an aqueous solution including ammonia and hydrogen peroxide.

In the step of FIG. 32, the NiSi₂ region exposed on the upper face of the channel semiconductor layer 3d is removed, and the region of the channel semiconductor layer 3d′ in each memory hole MH is elicited. This treatment is called an elicitation treatment, and the chemical liquid is called an elicitation liquid. Here, in the step of FIG. 32, the core insulator 3e may also be removed by the chemical liquid.

The chemical liquid used in FIG. 32 may be any etching solution that selectively dissolves the NiSi₂ region exposed on the upper face of the channel semiconductor layer 3d. The above-described dilute hydrofluoric acid aqueous solution, SC2, NC2, and SC1 selectively dissolve NiSi₂. Therefore, in the step of FIG. 32, only the NiSi₂ regions exposed on the upper face of the channel semiconductor layer 3d are dissolved, and the other regions in the channel semiconductor layer 3d remain. As a result, a cavity R is generated in the channel semiconductor layer 3d, making it possible to distinguish between the channel semiconductor layer 3d and the channel semiconductor layer 3d′, and thus making it possible to apply the crystal evaluation method of this embodiment. Note that the crystal evaluation method of this embodiment can be applied not only to the case in which the channel semiconductor layer 3d is partially removed but also to the case in which the channel semiconductor layer 3d is completely removed.

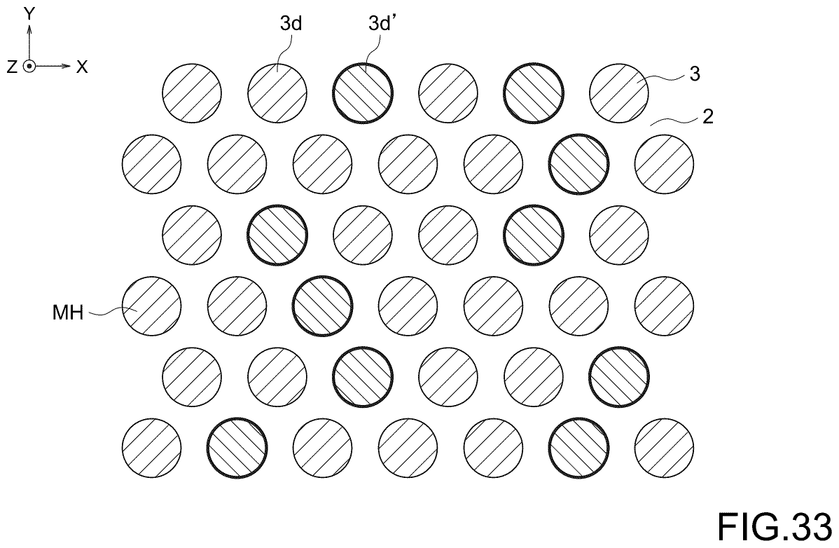

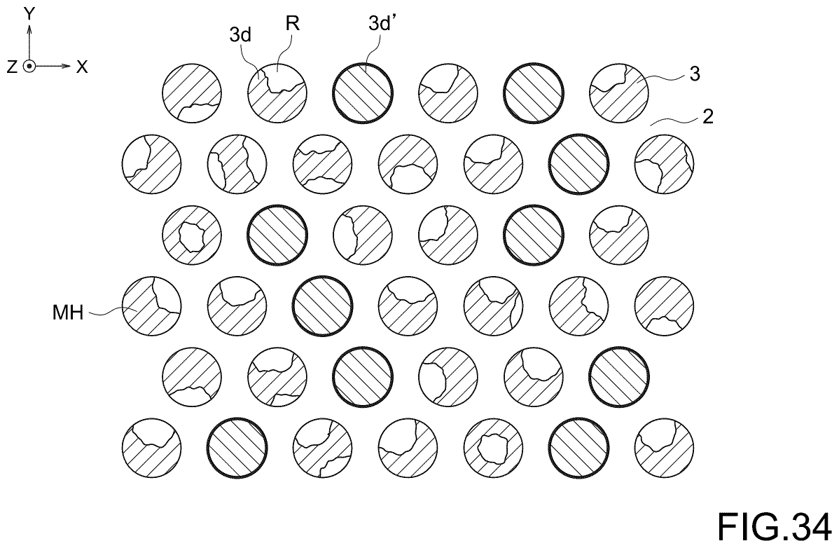

FIGS. 33 and 34 are plan views showing the modification of the second example of the crystal evaluation method of the first embodiment.

FIG. 33 is a plan view corresponding to the cross-sectional view of FIG. 31. For ease of understanding, FIG. 33 illustrates the memory holes MH (columnar portions 3) including the channel semiconductor layer 3d′ with a bold outline.

On the other hand, FIG. 34 is a plan view corresponding to the cross-sectional view of FIG. 32. FIG. 32 shows a plurality of cavities R formed near the bottom faces of the 29 memory holes MH by removing a plurality of NiSi₂ regions exposed on the upper face of the channel semiconductor layer 3d.

The process of this modification (FIGS. 30 to 34), like the process of FIGS. 26 to 29, makes it possible to treat the channel semiconductor layers 3d, 3d′ with a chemical liquid to determine the crystallization state of the channel semiconductor layer (channel semiconductor layers 3d, 3d′) in each memory hole MH. This modification makes it possible to omit gettering and reduce the number of steps in the crystal evaluation method.

### (3) Third Example

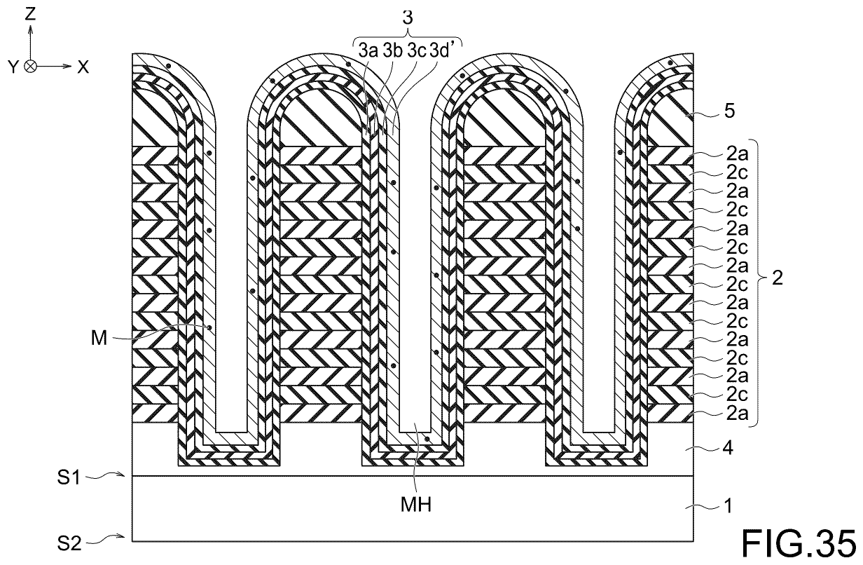

FIGS. 35 to 38 are cross-sectional views showing a third example of the crystal evaluation method of the first embodiment. In the third example, the annealing in FIG. 13 and the gettering in FIG. 15 are performed instead of the annealing in FIG. 8 and the gettering in FIG. 9. In other words, annealing is performed in a state in which the core insulator 3e, the semiconductor layer 6, and the getter layer 7 are not formed on the channel semiconductor layer 3d′, and then gettering is performed.

First, the steps of FIGS. 3 to 6 are performed (FIG. 35). FIG. 35 shows a channel semiconductor layer 3d′ to which a plurality of metal atoms M are added. The channel semiconductor layer 3d′ shown in FIG. 35 includes a region including metal atoms M and regions not including metal atoms M, like the channel semiconductor layer 3d′ shown in FIG. 16.

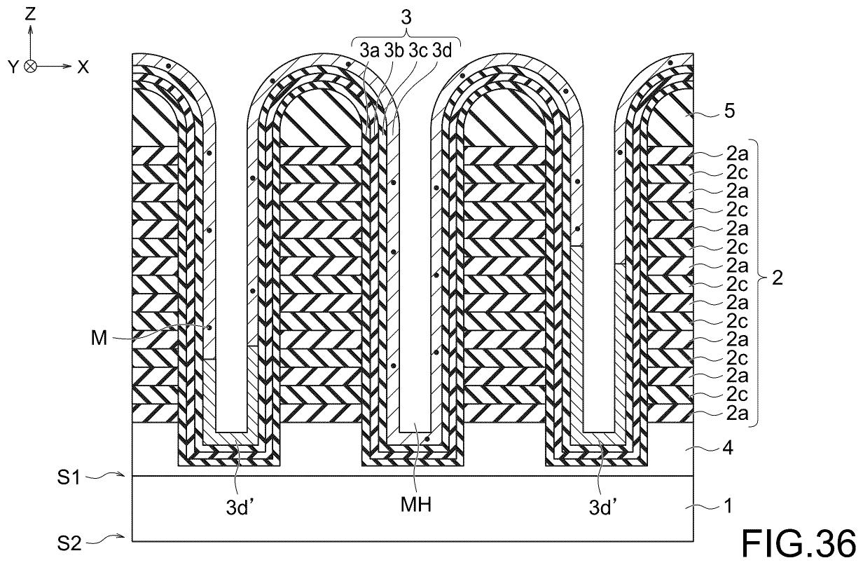

Next, the annealing of FIG. 13 is performed (FIG. 36). As a result, a portion of the channel semiconductor layer 3d′ is crystallized and changes into the channel semiconductor layer 3d. The remaining portion of the channel semiconductor layer 3d′ is not crystallized and remains as the channel semiconductor layer 3d′.

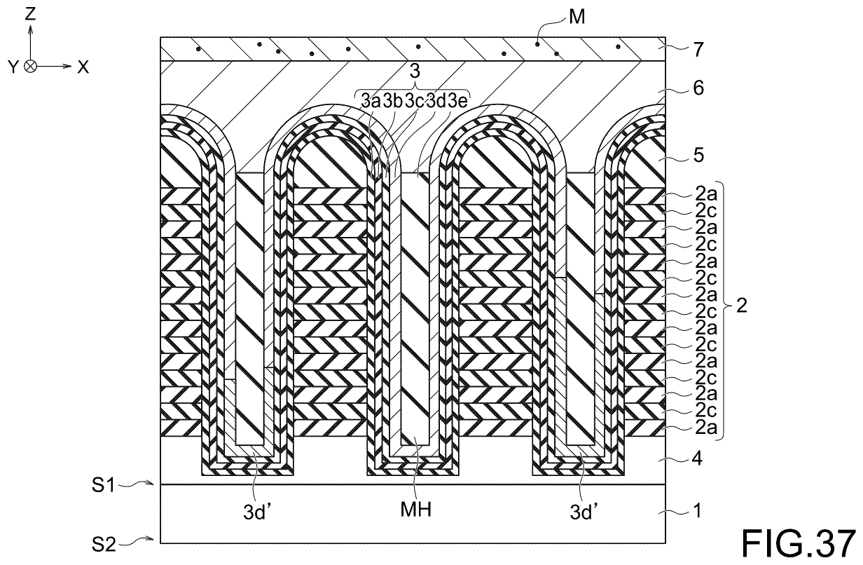

Next, the step of FIG. 14 and the gettering of FIG. 15 are performed (FIG. 37). As a result, the metal atoms M are removed from the channel semiconductor layer 3d.

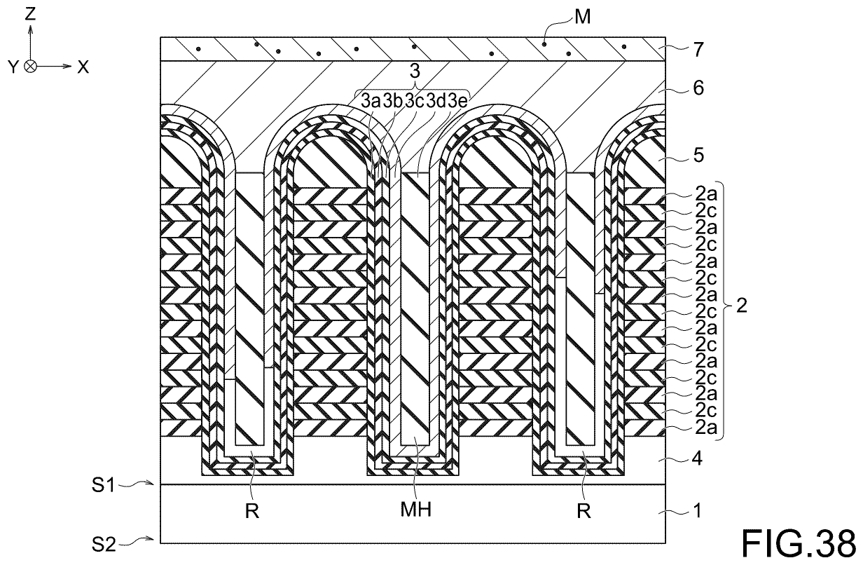

Next, the channel semiconductor layers 3d, 3d′ are treated with a chemical liquid (FIG. 38). Specifically, the chemical liquid is supplied to the channel semiconductor layers 3d, 3d′ provided on the substrate 1. The chemical liquid used in FIG. 38 is an etching solution that dissolves the channel semiconductor layer 3d′, like the chemical liquid used in FIG. 20. Therefore, in the step of FIG. 38, the channel semiconductor layer 3d′ of the channel semiconductor layers 3d, 3d′ is selectively removed by etching. FIG. 38 shows two cavities (spaces) R formed in two memory holes MH by removing the channel semiconductor layer 3d′, and the channel semiconductor layer 3d remaining after etching.

The supply of the chemical liquid to the channel semiconductor layers 3d, 3d′ is performed, for example, after cleavage is performed as in the first example (Method 1). This makes it possible to supply the chemical liquid to the channel semiconductor layers 3d, 3d′ without bonding the support substrate 12 or removing the substrate 1 as in the second example. On the other hand, when cleavage is not performed, for example, the getter layer 7, the semiconductor layer 6, and the core insulator 3e are removed, and then the chemical liquid is supplied from above to the channel semiconductor layers 3d, 3d′ (Method 2). The chemical liquid is supplied into concave portions formed in the channel semiconductor layers 3d, 3d′ by removing the core insulator 3e, and the channel semiconductor layers 3d, 3d′ are treated from the concave portions. This makes it possible to supply the chemical liquid to the channel semiconductor layers 3d, 3d′ without cleavage as in the first example, or without bonding the support substrate 12 or removing the substrate 1 as in the second example. Method 1 or Method 2 makes it possible to easily perform the crystal evaluation method of this embodiment.

This embodiment (third example), like the first and second examples, makes it possible to treat the channel semiconductor layers 3d, 3d′ with a chemical liquid to determine the crystallization state of the channel semiconductor layer (channel semiconductor layers 3d, 3d′) in each memory hole MH. The crystallization rate, imaging, profile acquisition, and the like in the third example are similar to those in the first and second examples.

In Method 2 of the third example, for example, the upper face of the channel semiconductor layer 3d in each memory hole MH is imaged from the +Z direction of the substrate 1. In this case, in the memory hole MH where the upper face of the tunnel insulator 3c is observed, the channel semiconductor layer in the memory hole MH can be determined to have included the channel semiconductor layers 3d, 3d′ before etching with the chemical liquid. Contrarily, in the memory hole MH where the upper face of the tunnel insulator 3c is not observed, the channel semiconductor layer in the memory hole MH can be determined to have included only the channel semiconductor layer 3d before etching with the chemical liquid. Note that in Method 1 of the third example, the cleavage plane of the stacked film 2 or the like may be imaged in the same manner as in the first example. In the third example, the above determination may be made by acquiring a profile instead of imaging.

As described above, in this embodiment, when the channel semiconductor layer 3d is formed from the channel semiconductor layer 3d′ using metal atoms M, a chemical liquid is used that dissolves the channel semiconductor layer 3d′ or the channel semiconductor layer 3d (NiSi₂ region), to evaluate the crystallization state of the channel semiconductor layer in each memory hole MH. For this reason, this embodiment makes it possible to suitably evaluate the crystallinity of the channel semiconductor layer in each memory hole MH.

For example, when the crystallization state is determined after gettering, the metal atoms M can be prevented from adversely affecting the chemical liquid. In contrast, when the crystallization state is determined before gettering, omission of gettering can reduce the number of steps in the crystal evaluation method. In addition, when the second or third example is employed, problems can be prevented that is associated with cleavage of the stacked film 2 and the like. Furthermore, when the third example is employed, it is possible to omit cleaving the stacked film 2 or the like, bonding the support substrate 12, and removing the substrate 1, allowing the crystal evaluation method of this embodiment to be performed easily.

### Second Embodiment

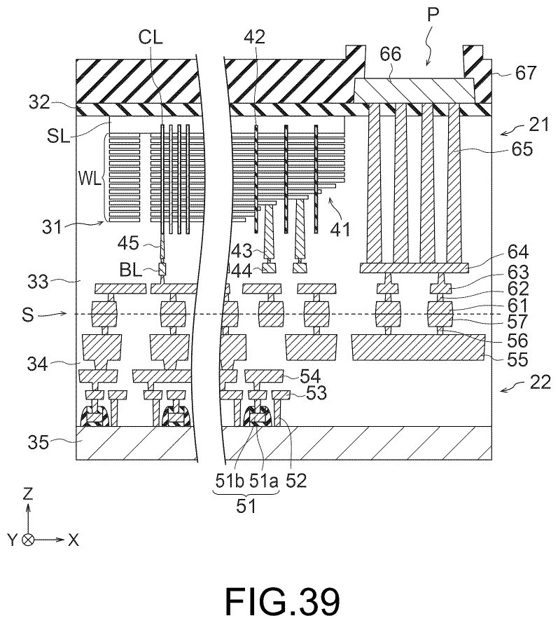

FIG. 39 is a cross-sectional view showing a structure of a semiconductor device of a second embodiment. The semiconductor device of this embodiment includes, for example, a three-dimensional semiconductor memory.

The semiconductor device of this embodiment includes an array chip 21 and a circuit chip 22 that are bonded. The semiconductor device of this embodiment is manufactured by bonding an array wafer including an array chip 21 and a circuit wafer including a circuit chip 22, as described below.

The array chip 21 includes a memory cell array 31 including a plurality of memory cells, an insulator 32 above the memory cell array 31, and an inter layer dielectric 33 below the memory cell array 31. The insulator 32 is, for example, a SiO₂ film. The inter layer dielectric 33 is, for example, a stacked film including a SiO₂ film and other insulators. A portion of the memory cell array 31 of this embodiment corresponds to the stacked film 2 of the first embodiment.

The circuit chip 22 is provided below the array chip 21. The reference character S denotes the bonding plane between the array chip 21 and the circuit chip 22. The circuit chip 22 includes an inter layer dielectric 34 below the inter layer dielectric 33, and a substrate 35 below the inter layer dielectric 34. The inter layer dielectric 34 is, for example, a stacked film including a SiO₂ film and other insulators. The substrate 35 is, for example, a semiconductor substrate such as a Si substrate.

FIG. 39 shows the X and Y directions that are parallel to the surface of the substrate 35 and perpendicular to each other, and the Z direction that is perpendicular to the surface of the substrate 35. The X direction, the Y direction, and the Z direction intersect with each other. In this embodiment, like the first embodiment, the +Z direction is defined as the upward direction, and the −Z direction is defined as the downward direction. The −Z direction may or may not coincide with the direction of gravity.

The array chip 21 includes a plurality of word lines WL as a plurality of electrode layers in the memory cell array 31. FIG. 39 shows a staircase structure 41 in the memory cell array 31 and a plurality of beams 42 provided in the staircase structure 41. Each word line WL extends in the X-direction, and is electrically connected to a word interconnect layer 44 via a contact plug 43. Each of the columnar portions CL penetrating the plurality of word lines WL is electrically connected to a bit line BL through a via plug 45, and is also electrically connected to a source line SL. The bit lines BL extend in the Y direction and are provided below the plurality of word lines WL. The source line SL extends in the X direction and is provided above the plurality of word lines WL. The columnar portions CL of this embodiment correspond to the columnar portions 3 of the first embodiment.

The circuit chip 22 includes a plurality of transistors 51. Each transistor 51 includes a gate insulator 51a and a gate electrode 51b provided in sequence on the substrate 35, and a source diffusion layer and a drain diffusion layer (not shown) provided in the substrate 35. The circuit chip 22 also includes a plurality of contact plugs 52 provided on the gate electrodes 51b, source diffusion layers, or drain diffusion layers of the plurality of transistors 51. The circuit chip 22 also includes an interconnect layer 53, an interconnect layer 54, and an interconnect layer 55. The interconnect layer 53 includes a plurality of interconnects and is provided on the plurality of contact plugs 52. The interconnect layer 54 includes a plurality of interconnects and is provided on the interconnect layer 53. The interconnect layer 55 includes a plurality of interconnects and is provided on the interconnect layer 54.

The circuit chip 22 further includes a plurality of via plugs 56 provided on the interconnect layer 55, and a plurality of metal pads 57 provided on the plurality of via plugs 56. The metal pad 57 is, for example, a metal layer including a Cu (copper) layer. The circuit chip 22 functions as a logic circuit that controls the operation of the array chip 21. This logic circuit is configured of a transistors 51 and the like, and is electrically connected to the metal pads 57.

The array chip 21 includes a plurality of metal pads 61 provided on the plurality of metal pads 57, and a plurality of via plugs 62 provided on the plurality of metal pads 61. The metal pad 61 is, for example, a metal layer including a Cu layer. The array chip 21 also includes an interconnect layer 63 and an interconnect layer 64. The interconnect layer 63 includes a plurality of interconnects and is provided on the plurality of via plugs 62. The interconnect layer 64 includes a plurality of interconnects and is provided on the interconnect layer 63. The above-described bit line BL is included in the interconnect layer 64. The logic circuit is electrically connected to the memory cell array 31 via the metal pads 61, 57, or the like, and controls the operation of the memory cell array 31 via the metal pads 61, 57, and the like.

The array chip 21 further includes a plurality of via plugs 65 provided on the interconnect layer 64, and metal pads 66 provided on the plurality of via plugs 65 and on the insulator 32. The array chip 21 also includes a passivation insulator 67 provided on the metal pads 66 and the insulator 32. The metal pad 66 is, for example, a metal layer including a Cu layer, and functions as an external connection pad (bonding pad) of the semiconductor device of this embodiment. The passivation insulator 67 is, for example, a stacked film including a SiO₂ film and a SiN film, and has an opening P through which the upper face of the metal pad 66 is exposed. The metal pad 66 can be electrically connected to a mounting board or other devices via the opening P by bonding wires, solder balls, metal bumps, or the like.

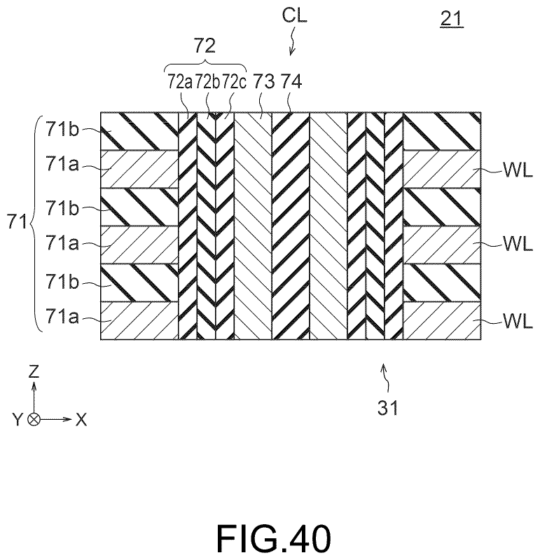

FIG. 40 is an enlarged cross-sectional view showing the structure of the semiconductor device of the second embodiment.

FIG. 40 shows the memory cell array 31 shown in FIG. 39. In FIG. 40, the memory cell array 31 includes a stacked film 71 including a plurality of electrode layers 71a and a plurality of insulators 71b alternately stacked in the Z direction. The plurality of electrode layers 71a function as, for example, the word lines WL. The electrode layer 71a is, for example, a metal layer including a Cu layer. Each insulator 71b is, for example, a SiO₂ film. The stacked film 71, the electrode layer 71a, and the insulator 71b of this embodiment respectively correspond to the stacked film 2, the electrode layer 2b, and the insulator 2a of the first embodiment.

FIG. 40 further shows one of the plurality of columnar portions CL shown in FIG. 39. Each columnar portion CL includes a memory insulator 72, a channel semiconductor layer 73, and a core insulator 74 provided in sequence on the side face of a stacked film 71. The memory insulator 72 includes a block insulator 72a, a charge storage layer 72b, and a tunnel insulator 72c provided in sequence on the side face of the stacked film 71. The block insulator 72a is, for example, a SiO₂ film. The charge storage layer 72b is, for example, an insulator such as a SiN film. The charge storage layer 72b may be a semiconductor layer such as a polysilicon layer. The charge storage layer 72b can store signal charges of a three-dimensional semiconductor memory. The tunnel insulator 72c is, for example, a SiO₂ film. The channel semiconductor layer 73 is, for example, a polysilicon layer. The channel semiconductor layer 73 functions as a channel of the three-dimensional semiconductor memory. The core insulator 74 is, for example, a SiO₂ film. The block insulator 72a, the charge storage layer 72b, the tunnel insulator 72c, the channel semiconductor layer 73, and the core insulator 74 of this embodiment respectively correspond to the block insulator 3a, the charge storage layer 3b, the tunnel insulator 3c, the channel semiconductor layer 3d, and the core insulator 3e of the first embodiment.

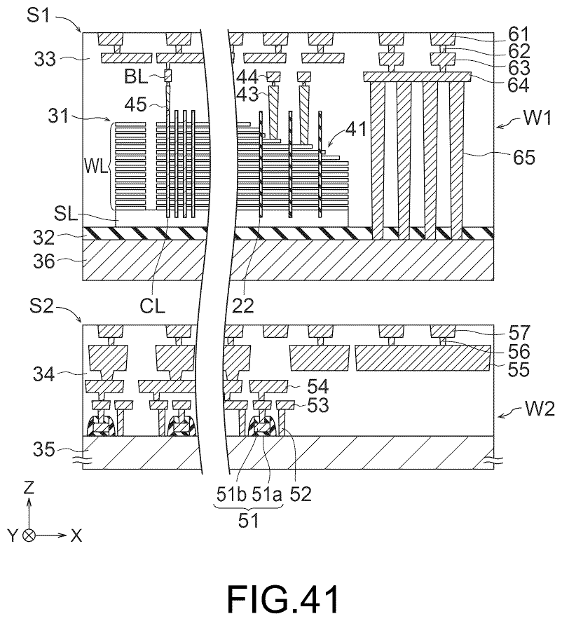

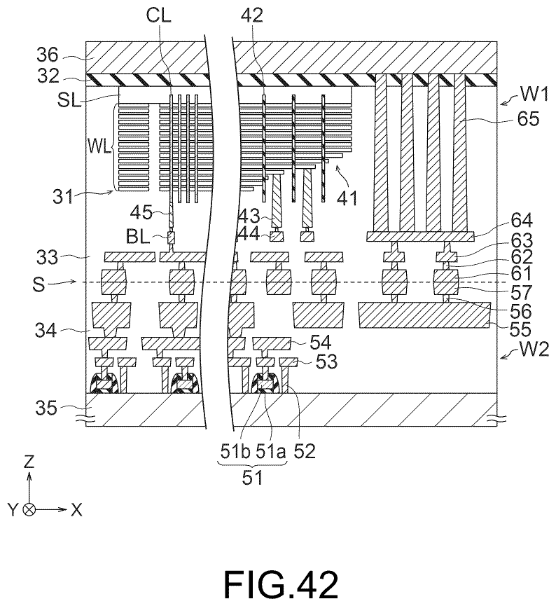

FIGS. 41 and 42 are cross-sectional views showing a method of manufacturing the semiconductor device of the second embodiment.

FIG. 41 shows an array wafer W1 including a plurality of array chips 21 and a circuit wafer W2 including a plurality of circuit chips 22. The orientation of the array wafer W1 in FIG. 41 is opposite to the orientation of the array chip 21 in FIG. 39. In this embodiment, an array wafer W1 and a circuit wafer W2 are bonded to manufacture a semiconductor device. FIG. 41 shows the array wafer W1 before its orientation is reversed for bonding, and FIG. 39 shows the array chip 21 after its orientation is reversed for bonding and it is then bonded and diced.

In FIG. 41, reference character S1 denotes the upper face of the array wafer W1, and reference character S2 denotes the upper face of the circuit wafer W2. The array wafer W1 includes a substrate 36 provided under an insulator 32. The substrate 36 is, for example, a semiconductor substrate such as a Si substrate. The substrate 36 of this embodiment corresponds to the substrate 1 of the first embodiment.

In this embodiment, as shown in FIG. 41, memory cell arrays 31, insulators 32, inter layer dielectrics 33, metal pads 61, via plugs 65, and the like are formed on the substrate 36 of the array wafer W1, and inter layer dielectrics 34, transistors 51, metal pads 57, and the like are formed on the substrate 35 of a circuit wafer W2. Next, as shown in FIG. 42, the array wafer W1 and the circuit wafer W2 are bonded by mechanical pressure so that the surface S1 and the surface S2 face each other. This causes the inter layer dielectric 33 to be bonded to the inter layer dielectric 34. Next, the array wafer W1 and the circuit wafer W2 are annealed. This joins the metal pad 61 and the metal pad 57. In this manner, the substrate 36 and the substrate 35 are bonded with the inter layer dielectrics 33 and 34 interposed therebetween.

Thereafter, the substrate 36 is removed by CMP, and the substrate 35 is thinned by CMP, and then the array wafer W1 and the circuit wafer W2 are cut into a plurality of chips (dicing). In this manner, the semiconductor device shown in FIG. 39 is manufactured. The metal pad 66 and the passivation insulator 67 are formed on the insulator 32 after the substrate 36 is removed and the substrate 35 is thinned.

Note that, FIG. 39 shows the boundary face between the inter layer dielectric 33 and the inter layer dielectric 34, and the boundary face between the metal pad 61 and the metal pad 57, but these boundary faces are generally no longer observed after the above-described annealing. However, the positions where these boundaries have been present can be presumed by detecting, for example, inclinations of the side faces of the metal pads 61 and side faces of the metal pads 57, or the positional deviation between the side faces of the metal pads 61 and the side faces of the corresponding metal pads 57.

According to this embodiment, the semiconductor device and the manufacturing method thereof according to the first embodiment can be applied to this embodiment. The crystal evaluation method of the first embodiment can be applied not only to the evaluation of the channel semiconductor layer 3d in the semiconductor device of the first embodiment, but also to the evaluation of the channel semiconductor layer 73 in the semiconductor device of this embodiment.

While certain embodiments have been described, these embodiments have been presented by way of example only, and are not intended to limit the scope of the inventions. Indeed, the novel methods described herein may be embodied in a variety of other forms; furthermore, various omissions, substitutions and changes in the form of the methods described herein may be made without departing from the spirit of the inventions. The accompanying claims and their equivalents are intended to cover such forms or modifications as would fall within the scope and spirit of the inventions.

1. A crystal evaluation method comprising:
forming, above a first substrate, a semiconductor layer that includes an amorphous layer containing metal atoms, the semiconductor layer including a first portion and a second portion;
crystallizing the first portion from the amorphous layer into a crystalline layer; and
treating the semiconductor layer with a chemical liquid that dissolves at least a part of the first portion or the second portion; and
determining a crystallization state of the semiconductor layer after the treatment.

2. The method of claim 1, further comprising forming a first film on the first substrate before the semiconductor layer is formed above the first substrate,
wherein the semiconductor layer is formed in the first film.

3. The method of claim 2, wherein the first film includes a stacked film including a plurality of first layers and a plurality of second layers that are alternately stacked.

4. The method of claim 2, further comprising:
bonding the first substrate and a second substrate to sandwich the first film and the semiconductor layer after the semiconductor layer is formed in the first film; and
removing the first substrate while remaining the first film and the semiconductor layer on the second substrate,
wherein the semiconductor layer is treated with the chemical liquid after the first substrate is removed.

5. The method of claim 4, wherein the chemical liquid is supplied to the semiconductor layer exposed on an upper face of the first film above the second substrate.

6. The method of claim 2, wherein the chemical liquid is supplied to the semiconductor layer exposed on a vertical cross section of the first film.

7. The method of claim 1, wherein the chemical liquid is supplied to the semiconductor layer provided on the first substrate.

8. The method of claim 1, wherein the chemical liquid is supplied to the semiconductor layer after removing the metal atoms from the semiconductor layer.

9. The method of claim 8, wherein the chemical liquid contains a liquid including dilute hydrofluoric acid and a liquid including hydrofluoric acid, nitric acid and acetic acid.

10. The method of claim 8, wherein the chemical liquid is a liquid that dissolves the first portion.

11. The method of claim 1, wherein the chemical liquid is supplied to the semiconductor layer in a state in which the semiconductor layer contains the metal atoms.

12. The method of claim 11, wherein the chemical liquid contains a liquid including dilute hydrofluoric acid, SC2, NC2 or SC1.

13. The method of claim 11, wherein the chemical liquid is a liquid that dissolves a region containing the metal atoms in the crystalline layer.

14. The method of claim 1, wherein the chemical liquid is supplied to the semiconductor layer in a state in which an insulator is formed in a concave portion provided in the semiconductor layer.

15. The method of claim 1, wherein the chemical liquid is supplied to the semiconductor layer in a state in which no insulator is formed in a concave portion provided in the semiconductor layer.

16. The method of claim 1, further comprising imaging the semiconductor layer or acquiring a profile of the semiconductor layer after treating the semiconductor layer with the chemical liquid,
wherein the crystallization state of the semiconductor layer is determined using an image obtained by the imaging or using the acquired profile.

17. The method of claim 16, wherein the image is taken by a scanning electron microscope or an optical microscope, or the profile is acquired by small-angle X-ray scattering.

18. A crystal evaluation method comprising:
forming, above a first substrate, a semiconductor layer including an amorphous layer;
crystallizing at least a portion of the semiconductor layer from the amorphous layer to a crystalline layer; and
treating the semiconductor layer with a chemical liquid that dissolves at least a part of the crystalline layer; and
determining a crystallization state of the semiconductor layer after the treatment.

19. The method of claim 18, wherein the amorphous layer containing metal atoms is formed as the semiconductor layer.

20. The method of claim 19, wherein the chemical liquid is supplied to the semiconductor layer in a state where the semiconductor layer contains the metal atoms.
